(19) United States
(12) Patent Application Publication
(10) Pub. No.: US 2025/0176181 A1
(43) Pub. Date: May 29, 2025

(54) SEMICONDUCTOR DEVICES WITH BYPASS VIAS

(71) Applicant: SAMSUNG ELECTRONICS CO., LTD., Suwon-si (KR)

(72) Inventor: Kang Lib Kim, Suwon-si (KR)

(21) Appl. No.: 18/736,223

(22) Filed: Jun. 6, 2024

(30) Foreign Application Priority Data
Nov. 28, 2023 (KR) 10-2023-0167766

(51) Int. Cl. H10B 43/27; H10B 41/27; H10B 41/41; H10B 43/40

(52) U.S. Cl. CPC H10B 43/27; H10B 41/27; H10B 41/41; H10B 43/40

(57) ABSTRACT

A semiconductor device includes a first semiconductor structure including a first substrate, circuit elements on the first substrate, and circuit interconnection lines on the circuit elements; a second semiconductor structure including a second substrate disposed on the first semiconductor structure, and having a first region, a first extension region disposed on one side of the first region, and a second extension region disposed on the other side of the first region; and bypass vias electrically connecting the first substrate and the second substrate; and through-interconnection regions including through-contact plugs passing through the second substrate and extending in the first direction to electrically connect the first semiconductor structure and the second semiconductor structure, wherein at least one through-interconnection region passes through the second substrate and extends from the first region to the first extension region in the second direction.

### CROSS-REFERENCE TO RELATED APPLICATION

This application claims the benefit of priority to Korean Patent Application No. 10-2023-0167766, filed on Nov. 28, 2023, in the Korean Intellectual Property Office, the disclosure of which is incorporated herein by reference in its entirety.

### BACKGROUND

In a data storage system requiring data storage, a semiconductor device for storing high-capacity data may be required. Accordingly, methods for increasing data storage capacity of semiconductor devices are being researched. For example, as a method for increasing data storage capacity of a semiconductor device, a semiconductor device including memory cells arranged three-dimensionally, instead of memory cells arranged two-dimensionally, has been proposed.

### SUMMARY

Some implementations according to this disclosure provide semiconductor devices and data storage systems having improved reliability.

According to some aspects of this disclosure, a semiconductor device includes a first semiconductor structure including a first substrate, circuit elements on the first substrate, and circuit interconnection lines on the circuit elements; a second semiconductor structure including a second substrate disposed on the first semiconductor structure, and having a first region, a first extension region disposed on one side of the first region, and a second extension region disposed on the other side of the first region; and bypass vias electrically connecting the first substrate and the second substrate, wherein the second semiconductor structure includes gate electrodes stacked on the second substrate to be spaced apart from each other in a first direction, perpendicular to the second substrate; channel structures passing through the gate electrodes in the first region to extend in the first direction; separation regions passing through the gate electrodes to extend in the first direction and in a second direction, perpendicular to the first direction, and spaced apart from each other in a third direction, perpendicular to the first and second directions; gate contact plugs contacting the gate electrodes extending in the first and second extension regions in a step shape in the second direction; and through-interconnection regions including through-contact plugs passing through the second substrate and extending in the first direction to electrically connect the first semiconductor structure and the second semiconductor structure in the first region, and an insulating region surrounding the through-contact plugs, wherein at least one through-interconnection region, among the through-interconnection regions, passes through the second substrate and extends from the first region to the first extension region in the second direction.

According to some aspects of this disclosure, a semiconductor device includes a first semiconductor structure including a first substrate, circuit elements on the first substrate, circuit interconnection lines on the circuit elements, and a first substrate insulating layer covering the circuit interconnection lines; a second semiconductor structure including a second substrate disposed on the first semiconductor structure, and having a first region, a first extension region disposed on one side of the first region, and a second extension region disposed on the other side of the first region; and bypass vias passing through the first substrate insulating layer and electrically connecting the first substrate and the second substrate, wherein the second substrate includes at least one slit extending from the first region to the first extension region.

According to some aspects of this disclosure, a data storage system includes a semiconductor storage device including a first semiconductor structure including a first substrate, circuit elements on the first substrate, and circuit interconnection lines on the circuit elements; a second semiconductor structure including a second substrate disposed on the first semiconductor structure, and having a first region, a first extension region disposed on one side of the first region, and a second extension region disposed on the other side of the first region; bypass vias electrically connecting the first substrate and the second substrate; and an input/output pad electrically connected to the circuit elements; and a controller electrically connected to the semiconductor storage device through the input/output pad and controlling the semiconductor storage device, wherein the second semiconductor structure includes gate electrodes stacked on the second substrate to be spaced apart from each other in a first direction, perpendicular to the second substrate; channel structures passing through the gate electrodes in the first region to extend in the first direction; separation regions passing through the gate electrodes to extend in the first direction and in a second direction, perpendicular to the first direction, and spaced apart from each other in a third direction, perpendicular to the first and second directions; gate contact plugs contacting the gate electrodes extending in the first and second extension regions in a step shape in the second direction; and through-interconnection regions including through-contact plugs passing through the second substrate and extending in the first direction to electrically connect the first semiconductor structure and the second semiconductor structure in the first region, and an insulating region surrounding the through-contact plugs, wherein at least one through-interconnection region, among the through-interconnection regions, passes through the second substrate and extends from the first region to the first extension region in the second direction.

### BRIEF DESCRIPTION OF THE DRAWINGS

The above and other aspects, features, and advantages will be more clearly understood from the following detailed description, taken in conjunction with the accompanying drawings, in which:

FIG. 1 is a schematic plan view of a semiconductor device according to some implementations.

FIG. 2 is a schematic plan view illustrating a mat.

FIG. 3 is a partially enlarged view of a semiconductor device according to some implementations.

FIGS. 4A and 4B are schematic cross-sectional views of a semiconductor device according to some implementations.

FIG. 5 is a perspective view illustrating an arrangement of a bypass via and a second substrate according to some implementations.

FIGS. 6 to 14 are schematic plan views of a semiconductor device according to some implementations.

FIGS. 15A to 15F are schematic cross-sectional views illustrating a method of manufacturing a semiconductor device according to some implementations.

FIG. 16 is a diagram schematically illustrating a data storage system including a semiconductor device according to some implementations.

FIG. 17 is a perspective view schematically illustrating a data storage system including a semiconductor device according to some implementations.

FIG. 18 is a cross-sectional view schematically illustrating a semiconductor package according to some implementations.

### DETAILED DESCRIPTION

Hereinafter, examples will be described with reference to the attached drawings. Unless otherwise specified, in this specification, terms such as ‘on,’ ‘upper portion,’ ‘upper surface,’‘below,’ ‘lower portion,’ ‘lower surface,’ ‘side surface,’ and the like may be based on the drawings, and may be actually changed depending on a direction in which a component is disposed.

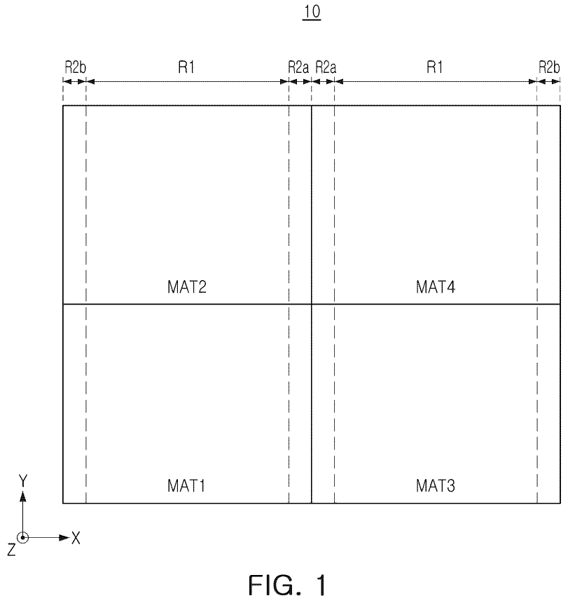

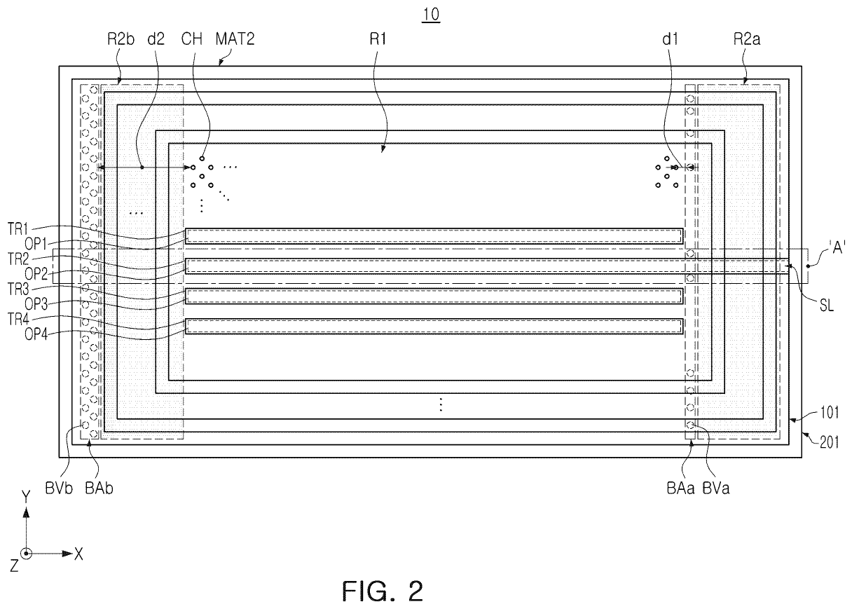

FIG. 1 is a schematic plan view of a semiconductor device according to some implementations, and FIG. 2 is a schematic plan view illustrating a mat, e.g., one of the four mats of FIG. 1.

As shown in FIGS. 1 and 2, a semiconductor device 10 may include a first substrate 201 and a second substrate 101, and the first substrate 201 and the second substrate 101 may be stacked on one another in a Z-direction, perpendicular to a surface of the second substrate 101. For example, the first substrate 201 may be disposed below (e.g., stacked below) the second substrate 101 in the Z-direction.

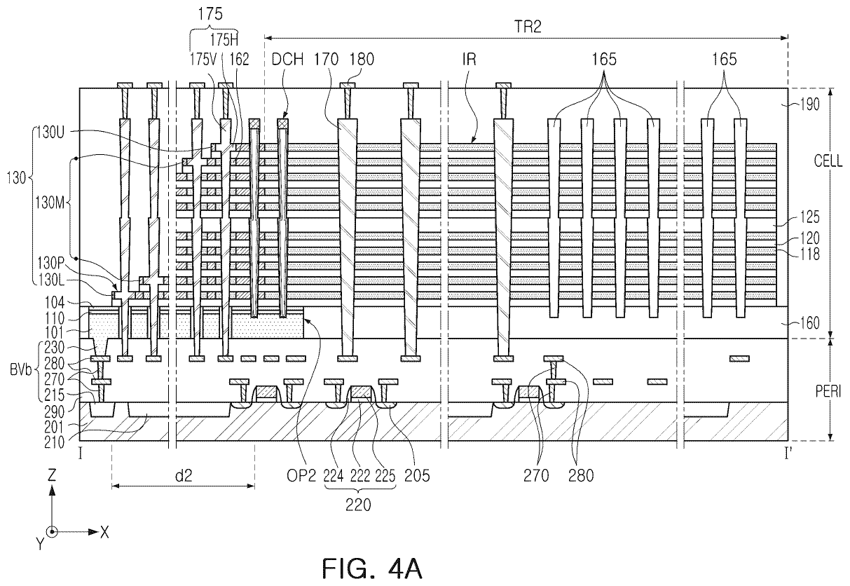

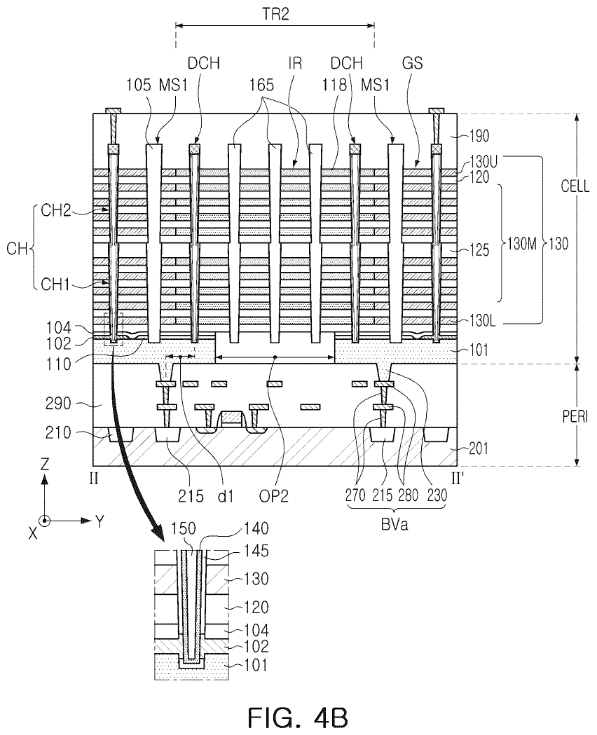

In some implementations, as shown in FIG. 4A, the semiconductor device 10 may include a peripheral circuit structure PERI in which a peripheral circuit region is formed on the first substrate 201, and a memory cell structure CELL including the second substrate 101, and may include bit line through-interconnection regions TR1 to TR4 (shown, for example, in FIG. 2) respectively including a through-contact plug 170 electrically connecting the peripheral circuit structure PERI and the memory cell structure CELL. The memory cell structure CELL may be disposed on the peripheral circuit structure PERI, and the bit line through-interconnection regions TR1 to TR4 may be arranged to pass through the memory cell structure CELL to connect the memory cell structure CELL and the peripheral circuit structure PERI. In some implementations, the memory cell structure CELL may be disposed below the peripheral circuit structure PERI.

In some implementations, the peripheral circuit structure PERI may form a peripheral circuit by forming transistors and metal patterns for interconnecting the transistors on the first substrate 201. After the peripheral circuit is formed in the peripheral circuit structure PERI, the memory cell structure CELL may be formed, but the scope of this disclosure is not limited to that order.

The memory cell structure CELL of the semiconductor device 10 may include a plurality of mats MAT1 to MAT4, shown, for example, in FIG. 1. The mats MAT1 to MAT4 may be arranged in a matrix arrangement or array in an X-direction and a Y-direction.

For example, for one semiconductor device 10, four mats MAT1 to MAT4 may be arranged. A mat in a lower left corner may be defined as a first mat MAT1, a second mat MAT2 may be defined to extend from the first mat MAT1 in the Y-direction, a third mat MAT3 may be defined to extend from the first mat MAT1 in the X-direction, and a fourth mat MAT4 may be defined to extend from the third mat MAT3 in the Y-direction. The MAT1 to MAT4 may include memory blocks and a set of a plurality of channel structures, respectively.

Each of the mats MAT1 to MAT4 may include a first region R1 spanning a distance in the X-direction, and a first extension region R2a and a second extension region R2b, on both sides of the first region R1, e.g., in the X direction.

The first extension region R2a may be an extension region disposed between neighboring mats MAT1 to MAT4, and the second extension region R2b may be defined as an extension region disposed in an edge region of the semiconductor device 10. Therefore, the first extension regions R2a of the first mat MAT1 and the third mat MAT3 may face each other, and the first extension regions R2a of the second mat MAT2 and the fourth mat MAT4 may face each other, and the second extension regions R2b may be disposed in the edge region of the semiconductor device 10. The first region R1 may be a region in which memory cells are disposed, and may be a region in which channel structures CH are disposed, and the first extension region R2a and the second extension region R2b may correspond to a region for electrically connecting the memory cells and the peripheral circuit structure PERI, and, for this purpose, may be a region in which gate electrodes extend with different lengths.

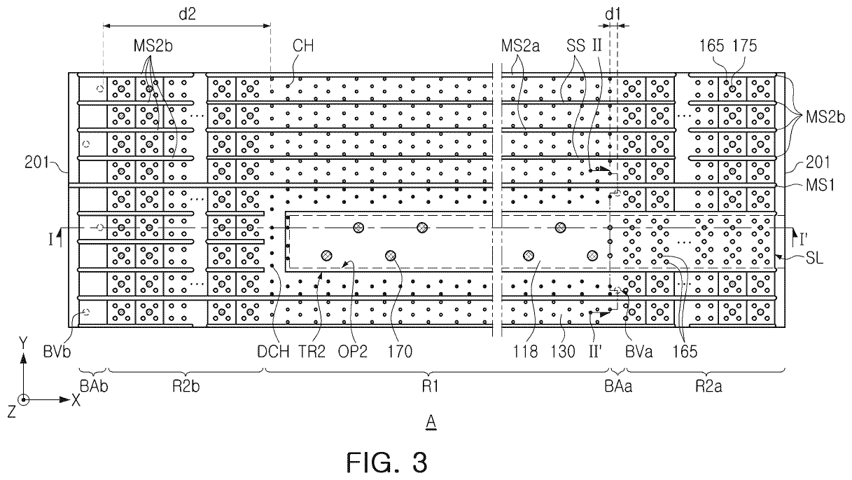

Referring to FIG. 2, each of the mats MAT1 to MAT4 may include a plurality of bit line through-interconnection regions TR1 to TR4 spaced apart from each other in the first region R1 in the Y-direction. For example, each of the first to fourth mats MAT1 to MAT4 may include four bit line through-interconnection regions TR1 to TR4, but the number thereof is not limited thereto. Additionally, in each of the first to fourth mats MAT1 to MAT4, the bit line through-interconnection regions TR1 to TR4 may be disposed in a central portion of the first region R1, the bit line through-interconnection regions TR1 to TR4 may extend in the first region R1 in the X-direction (e.g., have a longest dimension in the X-direction), and widths of the bit line through-interconnection regions TR1 to TR4 may be the same, but any of these characteristics may be changed in various implementations. A plurality of through-contact plugs 170 (shown, for example, in FIGS. 3-4A) respectively connected to a plurality of bit lines may be disposed in the bit line through-interconnection regions TR1 to TR4 of the memory cell structure CELL.

As illustrated in FIG. 2, the bit line through-interconnection regions TR1 to TR4 in each of the first to fourth mats MAT1 to MAT4 may be arranged in various shapes, and may include a first type bit line through-interconnection region (e.g., TR1) extending in the X-direction only in the first region R1, and a second type bit line through-interconnection region (e.g., TR2) extending from the first region R1 to the first extension region R2a in the X-direction.

The second type bit line through-interconnection regions may be spaced apart from each other in the Y-direction between the first type bit line through-interconnection regions, and may be arranged alternately, and the number of first type bit line through-interconnection regions may be larger than the number of second type bit line through-interconnection regions, but the present disclosure is not limited thereto.

The second substrate 101 in lower portions of the first type bit line through-interconnection regions may be removed to form closed-loop openings OP1, OP3, and OP4, and the second substrate 101 in lower portions of the second type bit line through-interconnection regions may be exposed to the first extension region R2a, to form an opening OP2 opened from one side of the second substrate 101 to the first region R1, forming a slit SL.

In FIG. 2, first, third, and fourth bit line through-interconnection regions TR1, TR3, and TR4 may be applied as the first type bit line through-interconnection regions, and a second bit line through-interconnection region TR2 may be the second type bit line through-interconnection region.

As shown in FIG. 4A, a substrate insulating layer 160 may be disposed in the openings OP1 to OP4 from which the second substrate 101 is removed such that the through-contact plugs 170 in the through-interconnection regions TR1 to TR4 extend to the peripheral circuit region PERI.

The mats MAT1 to MAT4 may include first and second bypass regions BAa and BAb for bypass connecting the first substrate 201 and the second substrate 101, respectively.

The second bypass region BAb may be disposed in each of the mats MAT between the second extension region R2b and edge regions of the mats MAT, and the first bypass region BAa may be disposed between the first region R1 and the first extension region R2a.

Each of the first and second bypass regions BAa and BAb may include a plurality of bypass vias BVa and BVb spaced apart from each other in the Y-direction, and the number and arrangement of the bypass vias BVa and BVb may be different. For example, the number of the second bypass vias BVb in the second bypass region BAb may be arranged to be greater than the number of the first bypass vias BVa in the first bypass region BAa, and a separation distance between the second bypass vias BVb is shorter than a separation distance between the first bypass vias BVa. Additionally, the second bypass vias BVb may be arranged in a plurality of rows, and each of the second bypass vias BVb and each of the first bypass vias BVa may be arranged such that a diameter of each of the second bypass vias BVb is longer than a diameter of each of the first bypass vias BVa, but the arrangements and relative sizes are not limited thereto.

The first bypass region BAa may include a plurality of first bypass vias BVa arranged to be spaced apart in the Y-direction between the first region R1 and the first extension region R2a. In each of the mats MAT, a distance d1 between the first bypass region BAa and the first region R1 may be shorter than a distance d2 between the second bypass region BAb and the first region R1. For example, the distance d1 between the first bypass vias BVa of the first bypass region BAa and a nearest channel structure CH or a dummy channel structure DCH (see FIG. 3) may be shorter than the distance d2 between the second bypass vias BVb of the bypass region BAb and the nearest channel structure CH or the dummy channel structure DCH.

For example, there may be an imbalance in the bypass vias BVa and BVb between the second bypass region BAb and the first bypass region BAa, since the first bypass regions BAa may be disposed close to each other in a region in which the mats MAT1 to MAT4 face each other, and many complex logic circuits may be disposed in the peripheral circuit region PERI, resulting in an insufficient space for the bypass vias BVa and BVb. Therefore, many of the bypass vias BVa and BVb may be arranged in the edge region of the semiconductor device 10, for example, in the second bypass region BAb, at an external side of the second extension region R2b in each of the mats MAT.

The bypass vias BVa and BVb may be structures for preventing occurrence of arcing, and load may be determined depending on the number of adjacent channel structures CH and an effective area of the second substrate 101. A bypass path from each of the channel structures CH to the bypass vias BVa and BVb may be implemented with many resistor networks in the second substrate 101 formed in a plane. In this case, the path from the channel structure CH to the bypass vias BVa and BVb located at the shortest distance has the lowest path resistance, and may be thus defined as the bypass path of the channel structure CH. Therefore, an effective area including regions in which channel structures of the bypass path are located may be allocated to each of the bypass vias.

In the second bypass region BAb, as the second bypass region BAb is separated from a nearest channel structures CH by a predetermined distance or more (d2), a current path, which is a bypass path, may be distributed in various manners, and the second bypass vias BVb may be arranged in a relatively large number and a relatively high density, to alleviate excessive load on some of the bypass vias BVb.

In the first bypass region BAa, bypass thereof may be performed in a smaller number than the second bypass vias BVb, and to prevent overload of the first bypass vias BAa, at least one of the bit line through-interconnection regions TR1 to TR4, for example, the second bit line through-interconnection region TR2, may extend from the first region R1 to the first extension region R2a. Accordingly, the second substrate 101 in a lower portion of the second bit line through-interconnection region TR2 may be removed to form a long slit SL in the X-direction.

In this manner, at least one of the bit line through-interconnection regions TR1 to TR4 may extend from the first region R1 to cross the first extension region R2a, and may form a slit SL from one side of the second substrate 101 to the first region R1 in a lower portion thereof, to advantageously disperse a current path, which is a bypass path, flowing from the second substrate 101 to the first substrate 201 through the first bypass vias BAa.

Hereinafter, examples will be described in more detail with reference to FIGS. 3, 4A, 4B, and 5.

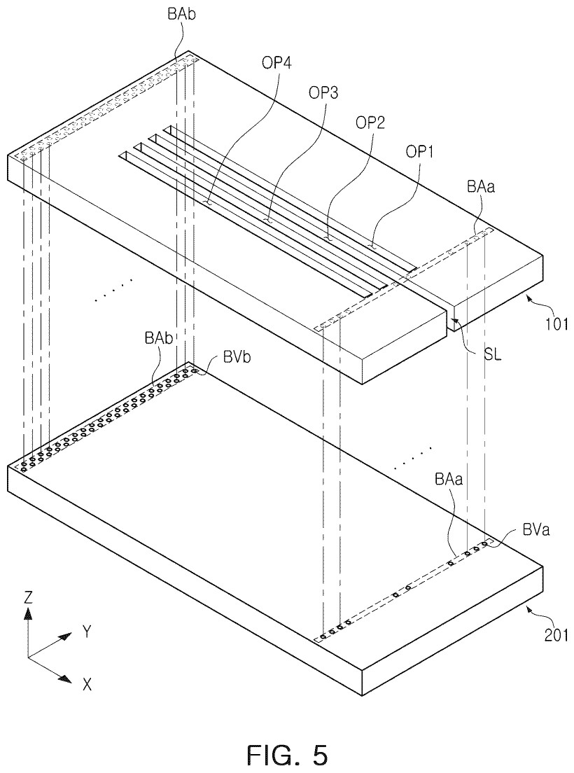

FIG. 3 is a partially enlarged view of a semiconductor device according to some implementations, FIGS. 4A and 4B are schematic cross-sectional views of a semiconductor device according to some implementations, and FIG. 5 is a view illustrating arrangement of a bypass via and a second substrate according to some implementations. FIG. 3 may be an enlarged view of portion A of FIG. 2, and FIGS. 4A and 4B may illustrate the cross-sections of FIG. 3, respectively, taken along lines I-I′ and II-II′. Elements of FIGS. 3 to 5 can have the characteristics described for those elements with respect to FIGS. 1 to 2 above.

Referring to FIGS. 3 to 5, a peripheral circuit structure PERI of a semiconductor device 10 may include a first substrate 201, source/drain regions 205 and element isolation layers 210 in the first substrate 201, circuit elements 220, circuit contact plugs 270, circuit interconnection lines 280, and a peripheral region insulating layer 290, arranged on the first substrate 201.

The first substrate 201 may have an upper surface extending in the X- and Y-directions. An active region may be defined in the first substrate 201 by the element isolation layers 210. The source/drain regions 205 containing an impurity may be disposed in a portion of the active region. The first substrate 201 may include a semiconductor material, such as a group IV semiconductor, a group III-V compound semiconductor, or a group II-VI compound semiconductor. The first substrate 201 may be provided as a bulk wafer or an epitaxial layer.

The circuit elements 220 may include planar transistors. Each of the circuit elements 220 may include a circuit gate dielectric layer 222, a spacer layer 224, and a circuit gate electrode 225. The source/drain regions 205 may be disposed in the first substrate 201 on both sides of the circuit gate electrode 225.

The peripheral region insulating layer 290 may be disposed on a circuit element 220 on the first substrate 201. The circuit contact plugs 270 may pass through the peripheral region insulating layer 290, and may be connected to the source/drain regions 205. An electrical signal may be applied to the circuit element 220 through the circuit contact plugs 270. The circuit contact plugs 270 may also be connected to the circuit gate electrode 225 (e.g., in another region). The circuit interconnection lines 280 may be connected to the circuit contact plugs 270, and may be arranged in multiple layers.

A memory cell structure CELL may include a first region R1, a first extension region R2a, and a second extension region R2b, and may include a second substrate 101 disposed in the first region R1, the first extension region R2a, and the second extension region R2b. The memory cell structure CELL may include a first horizontal conductive layer 102 on the second substrate 101 in the first region R1; a horizontal insulating layer 110 disposed in parallel with the first horizontal conductive layer 102 on the second substrate 101 in the first and second extension regions R2a and R2b; a second horizontal conductive layer 104 on the first horizontal conductive layer 102 and the horizontal insulating layer 110; gate electrodes 130 stacked on the second horizontal conductive layer 104; first and second separation regions MS1, MS2a, and MS2b, extending to pass through a stack structure GS of the gate electrodes 130; upper separation regions SS passing through a portion of the stack structure GS; and channel structures CH disposed to pass through the stack structure GS. The memory cell structure CELL may further include interlayer insulating layers 120, interconnection lines 180, and cell region insulating layers 190, alternately stacked with the gate electrodes 130, on the second substrate 101.

The first region R1 may be a region in which the gate electrodes 130 are vertically stacked on the second substrate 101 and the channel structures CH are disposed, and may be a region in which memory cells are disposed, and the first extension region R2a and the second extension region R2b may be regions in which the gate electrodes 130 extend with different lengths, and may correspond to regions for electrically connecting the memory cells to the peripheral circuit structure PERI. The first extension region R2a may be disposed in a region facing the first extension region R2a of a neighboring mat MAT in the first region R1, and the second extension region R2b may be disposed in an edge region of the semiconductor device 10 in the first region R1.

Accordingly, in one mat MAT, the second extension region R2b, the first region R1, and the first extension region R2a may be sequentially arranged in the X-direction. In the following example, the second mat MAT2 may be described with reference to the first extension region R2a, and the first extension region R2a is illustrated to be disposed on a right side of the first region R1, but the present disclosure is not limited thereto.

The second substrate 101 may have an upper surface extending in the X- and Y-directions. The second substrate 101 may include a semiconductor material, such as a group IV semiconductor, a group III-V compound semiconductor, or a group II-VI compound semiconductor. For example, the group IV semiconductor may include silicon, germanium, or silicon-germanium. The second substrate 101 may further include an impurity. The second substrate 101 may be provided as a polycrystalline semiconductor layer such as a polycrystalline silicon layer, or an epitaxial layer.

The first and second horizontal conductive layers 102 and 104 may be sequentially stacked and disposed on the upper surface of the second substrate 101 in the first region R1. The first horizontal conductive layer 102 may not extend to the first and second extension regions R2a, R2b of the second substrate 101, and the second horizontal conductive layer 104 may extend to the first and second extension regions R2a, R2b.

The first horizontal conductive layer 102 may function as a portion of a common source line of the semiconductor device 10, for example, may function as a common source line, together with the second substrate 101. As illustrated in the enlarged view of FIG. 4B, the first horizontal conductive layer 102 may be directly connected to a channel layer 140 around the channel layer 140.

The second horizontal conductive layer 104 may be bent in a region in which the first horizontal conductive layer 102 and the horizontal insulating layer 110 are not disposed, and may be in contact with the second substrate 101. The second horizontal conductive layer 104 may cover an end portion of the first horizontal conductive layer 102 or an end portion of the horizontal insulating layer 110, and may be bent to extend onto the second substrate 101.

The first and second horizontal conductive layers 102 and 104 may include a semiconductor material. For example, the first and second horizontal conductive layers 102 and 104 may both include polycrystalline silicon. In at least this case the first horizontal conductive layer 102 may be a doped layer, and the second horizontal conductive layer 104 may be a doped layer or a layer containing an impurity diffused from the first horizontal conductive layer 102. In some implementations, the second horizontal conductive layer 104 may be replaced with an insulating layer.

The horizontal insulating layer 110 may be disposed on the second substrate 101 parallel to the first horizontal conductive layer 102 in at least a portion of the first and second extension regions R2a and R2b. The horizontal insulating layer 110 may include first to third horizontal insulating layers sequentially stacked on the second substrate 101 in the first and second extension regions R2a and R2b. The horizontal insulating layer 110 may include one or more layers that remain after a portion of the horizontal insulating layer 110 is replaced with the first horizontal conductive layer 102 during a process of manufacturing the semiconductor device 10.

The horizontal insulating layer 110 may include silicon oxide, silicon nitride, silicon carbide, or silicon oxynitride.

The gate electrodes 130 may be vertically spaced apart and stacked on the second substrate 101 to form the stack structure GS. The gate electrodes 130 may include a lower gate electrode 130L forming a gate of a ground selection transistor, memory gate electrodes 130M forming a plurality of memory cells, and upper gate electrodes 130U forming gates of string selection transistors. The number of memory gate electrodes 130M forming memory cells may be determined depending on capacity of the semiconductor device 10. Depending on the implementation, the upper and lower gate electrodes 130U and 130L may be one or two or more, respectively, and may have a structure identical to or different from those of the memory gate electrodes 130M. In some implementations, the gate electrodes 130 may further include a gate electrode 130 disposed above the upper gate electrodes 130U and/or below the lower gate electrodes 130L and constituting an erase transistor used for an erase operation using a gate induced drain leakage (GIDL) phenomenon. Also, a portion of the gate electrodes 130, e.g., memory gate electrodes 130M adjacent to the upper or lower gate electrodes 130U and 130L, may be dummy gate electrodes.

The gate electrodes 130 may be vertically spaced apart from each other and stacked in the first region R1, and may extend with different lengths from the first region R1 to the second extension regions R2a and R2b to form a stepped structure. Due to the stepped structure, the gate electrodes 130 form a step shape in which a lower gate electrode 130 extends longer than an upper gate electrode 130, and may provide end portions exposed from the interlayer insulating layers 120 in an upward direction. In some implementations, in the end portions, the gate electrodes 130 may have an increased thickness.

As illustrated in FIG. 3, the gate electrodes 130 may be arranged to be separated from each other in the Y-direction by a first separation region MS1 extending in the X-direction. The gate electrodes 130 between a pair of first separation regions MS1 may form a memory block, but a range of the memory block is not limited thereto. Some of the gate electrodes 130, for example, the memory gate electrodes 130M, may form one layer in one memory block.

The gate electrodes 130 may include a metal material, for example, tungsten (W). In some implementations, the gate electrodes 130 may include polycrystalline silicon or a metal silicide material. In some implementations, the gate electrodes 130 may further include a diffusion barrier, and, for example, the diffusion barrier may include tungsten nitride (WN), tantalum nitride (TaN), titanium nitride (TiN), or a combination thereof.

The interlayer insulating layers 120 may be disposed between the gate electrodes 130. Like the gate electrodes 130, the interlayer insulating layers 120 may be arranged to be spaced apart from each other in a direction perpendicular to the upper surface of the second substrate 101 (e.g., the Z-direction), and extend in the X-direction. The interlayer insulating layers 120 may include an insulating material such as silicon oxide or silicon nitride.

The first and second separation regions MS1, MS2a, and MS2b may be arranged to pass through the gate electrodes 130 and extend in the X-direction. The first and second separation regions MS1, MS2a, and MS2b may be arranged parallel to each other. The first and second separation regions MS1, MS2a, and MS2b may pass entirely through the gate electrodes 130 stacked on the second substrate 101 and be connected to the second substrate 101. First separation regions MS1 may extend as one in the X-direction, and second separation regions MS2 may extend intermittently between a pair of first separation regions MS1, or may in another arrangement. For example, second central separation regions MS2a may extend as one in the first region R1, and may extend intermittently in the first and second extension regions R2a and R2b in the X-direction. Second auxiliary separation regions MS2b may be disposed only in the first and second extension regions R2a and R2b, and may extend intermittently in the X-direction. In various implementations, an arrangement order, the number, and the like of the first and second separation regions MS1, MS2a, and MS2b are not limited to those illustrated in FIGS. 3 and 4A to 4B.

The first and second separation regions MS1, MS2a, and MS2b may not overlap the bit line through-interconnection regions TR1 to TR4, and may be spaced apart from the bit line through-interconnection regions TR1 to TR4. According to this arrangement of the first and second separation regions MS1, MS2a, and MS2b, a separation region closest to the bit line through-interconnection regions TR1 to TR4 may be one of the second separation regions MS2a and MS2b.

As illustrated in FIGS. 4A and 4B, a separation insulating layer 105 may be disposed in the first and second separation regions MS1, MS2a, and MS2b. The separation insulating layer 105 may have a shape having a width that decreases toward the second substrate 101 due to a high aspect ratio thereof, but is not limited thereto, and may have a side surface perpendicular or substantially perpendicular to the upper surface of the second substrate 101. In some implementations, a conductive layer may be further disposed in the separation insulating layer 105 in the first and second separation regions MS1, MS2a, and MS2b. In this case, the conductive layer may function as a common source line or a contact plug connected to the common source line of the semiconductor device 10.

As illustrated in FIG. 3, the upper separation regions SS may extend between the first separation regions MS1 and the second central separation region MS2a and between the second central separation regions MS2a in the first region R1, extending in the X-direction. The upper separation regions SS may be disposed in a region in which the bit line through-interconnection regions TR1 to TR4 are not disposed. The upper separation regions SS may be disposed to pass through a portion of the gate electrodes 130 including an uppermost upper gate electrode 130U, among the gate electrodes 130. For example, the upper separation regions SS may separate a total of three gate electrodes 130, including the upper gate electrodes 130U, from each other in the Y-direction. The number of gate electrodes 130 separated by the upper separation regions SS may be changed in various implementations. The upper gate electrodes 130U separated by the upper separation regions SS may form different string selection lines. The upper separation regions SS may include an insulating material. The insulating material may include, for example, silicon oxide, silicon nitride, or silicon oxynitride.

The channel structures CH may form one memory cell string, respectively, and may be arranged to be spaced apart from each other in rows and columns in the first region R1. The channel structures CH may be arranged to form a grid pattern or may be arranged in a zigzag shape in one direction. The channel structures CH may include vertically stacked lower and upper channel structures CH1 and CH2. The channel structures CH may have a shape in which the lower channel structures CH1 and the upper channel structures CH2 are connected, and may have a bent portion due to a difference in width in a connection region. In some implementations, the number of channel structures stacked in the Z-direction may be changed. Each of the channel structures CH may include a channel layer 140, a gate dielectric layer 145, a channel buried insulating layer 150, and a channel pad in an upper end portion, arranged in a channel hole.

In some implementations, the channel structures CH disposed within a certain range from the bit line through-interconnection regions TR1 to TR4 may include dummy channel structures DCH not substantially forming a memory cell string.

As illustrated in the enlarged view of FIG. 4B, the channel layer 140 may be disposed in the channel structures CH. In the channel structures CH, the channel layer 140 may be formed in an annular shape surrounding the channel buried insulating layer 150, but, depending on the implementation, may have a pillar shape such as a cylinder or a prism, e.g., without the channel buried insulating layer 150. The channel layer 140 may be connected to the first horizontal conductive layer 102 in a lower portion. The channel layer 140 may include a semiconductor material such as polycrystalline silicon or single crystalline silicon.

Channel pads may be disposed on the channel layer 140 in the channel structures CH. The channel pads may be arranged to cover an upper surface of the channel buried insulating layer 150 and be electrically connected to the channel layer 140. The channel pads may include doped polycrystalline silicon, for example.

The gate dielectric layer 145 may be disposed between the gate electrodes 130 and the channel layer 140. The gate dielectric layer 145 may include a tunneling layer, a charge storage layer, and a blocking layer, sequentially stacked from the channel layer 140. The tunneling layer may tunnel charges into the charge storage layer, and may include, for example, silicon oxide (SiO₂), silicon nitride (Si₃N₄), silicon oxynitride (SiON), or a combination thereof. The charge storage layer may be a charge trap layer or a floating gate conductive layer. The blocking layer may include silicon oxide (SiO₂), silicon nitride (Si₃N₄), silicon oxynitride (SiON), a high-κ dielectric material, or a combination thereof. In some implementations, at least a portion of the gate dielectric layer 145 may extend along the gate electrodes 130 in a horizontal direction.

The dummy channel structures DCH may have the same or similar structure as the channel structures CH, and may be arranged to be spaced apart from each other in rows and columns in a portion of the first region R1 and the first and second extension regions R2a and R2b. The dummy channel structures DCH may not be electrically connected to interconnection structures in an upper portion and/or may not form a memory cell string in the semiconductor device 10, unlike the channel structures CH. In the first region R1, the dummy channel structures DCH may be disposed in a region adjacent to the bit line through-interconnection regions TR1 to TR4 and in a region adjacent to the first and second extension regions R2a and R2b.

As illustrated in FIGS. 4A and 4B, the dummy channel structures DCH disposed adjacent to the bit line through-interconnection regions TR1 to TR4 may be disposed to pass through the horizontal insulating layer 110 in the Z-direction. The dummy channel structures DCH may have lower portions surrounded by the second horizontal conductive layer 104 and the horizontal insulating layer 110, and may be spaced apart from the first horizontal conductive layer 102. The dummy channel structures DCH closest to the bit line through-interconnection regions (TR2), for example, first dummy channel structures, may pass through the interlayer insulating layers 120 and sacrificial insulating layers 118, and may pass through the second horizontal conductive layer 104 and the horizontal insulating layer 110 in a lower end portion.

Next to the first dummy channel structure, dummy channel structures DCH disposed adjacent to the bit line through-interconnection regions TR1 to TR4, for example, second dummy channel structures, may pass through the interlayer insulating layers 120 and the gate electrodes 130, and may pass through the second horizontal conductive layer 104 and the horizontal insulating layer 110 in a lower end portion.

The bit line through-interconnection regions TR1 to TR4 may be regions including interconnection structures for electrically connecting the memory cell structure CELL and the peripheral circuit structure PERI to each other, and a second bit line through-interconnection region TR2 enlarged in FIG. 3 may be a second type of bit line through-interconnection region extending from the first region R1 to the first extension region R2a in FIG. 2.

Each of the bit line through-interconnection regions TR1 to TR4 may include through-contact plugs 170 passing through the second substrate 101 to extend in the Z-direction, and an insulating region IR surrounding the through-contact plugs 170.

As illustrated in FIGS. 2 and 3, the bit line through-interconnection regions TR1 to TR4 may be arranged to be spaced apart from the first and second separation regions MS1, MS2a, and MS2b. The bit line through-interconnection regions TR1 to TR4 may be spaced apart from adjacent first separation regions MS1 in the Y-direction, and may be disposed in a central portion of a pair of first separation regions MS1. In some implementations, based on this arrangement, the sacrificial insulating layers 118 may remain in bit line through-interconnection regions TR1 to TR4, respectively.

The second bit line through-interconnection region TR2 may extend toward the first extension region R2a, and may thus have a shape spaced apart from the second separation regions MS2b disposed in the second extension region R2b and biased to one side from the first region R1 to the first extension region R2a. The sacrificial insulating layers 118 may remain in the second bit line through-interconnection region TR2.

The insulating region IR may pass through the memory cell structure CELL, and may be disposed in parallel with the second substrate 101 and the gate electrodes 130. The gate electrode 130 may not extend or be disposed in the insulating region IR, and may include an insulating stack structure formed of an insulating material. The insulating regions IR may include the substrate insulating layer 160, which may be a first insulating layer disposed parallel to the second substrate 101 and on the same height level as the second substrate 101, and the interlayer insulating layers 120 and the sacrificial insulating layers 118, which may be second and third insulating layers alternately stacked on the upper surface of the second substrate 101.

The substrate insulating layer 160, which may be the first insulating layer, may be disposed in a region from which a portion of the second substrate 101, a portion of the horizontal insulating layer 110, and a portion of the second horizontal conductive layer 104 are removed, and may be disposed to be surrounded by the second substrate 101, the horizontal insulating layer 110, and the second horizontal conductive layer 104. A lower surface of the substrate insulating layer 160 may be coplanar with a lower surface of the second substrate 101 or may be located on a lower level than the lower surface of the second substrate 101. In some implementations, the substrate insulating layer 160 may include a plurality of insulating layers. The second insulating layer may be formed by extending the interlayer insulating layers 120, and may be thus located on substantially the same height level as the interlayer insulating layers 120. The third insulating layer may include the sacrificial insulating layers 118, and may be located on substantially the same height level as the gate electrodes 130. The sacrificial insulating layers 118 may extend partially toward an external side of the first to fourth bit line through-interconnection regions TR1 to TR4, e.g., when the bit line through-interconnection regions TR1 to TR4 are defined based on the area of the substrate insulating layer 160.

The substrate insulating layer 160, the interlayer insulating layers 120, and the sacrificial insulating layers 118 forming the insulating region IR may be formed of an insulating material. For example, the substrate insulation layer 160, the interlayer insulation layers 120, and the sacrificial insulation layers 118 may include silicon oxide, silicon nitride, or silicon oxynitride, respectively. The substrate insulating layer 160 and the sacrificial insulating layers 118 may have different widths or may have the same width.

As shown in FIG. 2, the second substrate 101 may be formed with an opening OP2 forming a long slit SL from the first region R1 to the first extension region R2a in a region corresponding to the second bit line through-interconnection region TR2, and one side surface of the second substrate 101 may be opened by the slit SL. The substrate insulating layer 160 may be disposed in the slit SL. As shown in FIG. 2, the second substrate 101 may have openings OP1, OP3, and OP4 in the first region R1 in regions corresponding to the first, third, and fourth bit line through-interconnection regions TR1, TR3, and TR4, and the substrate insulating layer 160 may be disposed to fill the openings OP1, OP3, and OP4.

The through-contact plugs 170 may be disposed in the first region R1, may pass entirely through the insulating region IR in upward and downward directions to extend perpendicularly to the upper surface of the first substrate 201, and may electrically connect the memory cell structure CELL and the circuit elements 220 of the peripheral circuit structure PERI. For example, the through-contact plugs 170 may electrically connect the gate electrodes 130 or the channel structures CH of the memory cell structure CELL and the circuit elements 220 of the peripheral circuit structure PERI. The through-contact plugs 170 may be connected to the interconnection lines 180, which may be the upper interconnection structure, at an upper portion of the through-contact plugs 170, and may instead or additionally be connected to a separate contact plug. The through-contact plugs 170 may be connected to circuit interconnection lines 280, which may be lower interconnection structures, at a lower portion of the through-contact plugs 170.

The through-contact plugs 170 may pass through the interlayer insulating layers 120 and the sacrificial insulating layers 118 of the insulating region IR, and may pass through the substrate insulating layer 160 in a lower portion. The number, shapes, and types of the through-contact plugs 170 in one bit line through-interconnection region may vary in various implementations. In some implementations, the through-contact plugs 170 may have a shape in which a plurality of layers are connected. In some implementations, in addition to the through-contact plugs 170, additional interconnection structures in the form of interconnection lines may be disposed in the insulation region IR. The through-contact plugs 170 may include a conductive material, for example, tungsten (W), copper (Cu), aluminum (Al), or the like.

Gate contact plugs 175 may be connected to contact regions 130P of the gate electrodes 130. The gate contact plugs 175 may pass through at least a portion of the cell region insulating layer 190, and may be connected to each of the contact regions 130P of the gate electrodes 130 exposed in an upward direction. The gate contact plugs 175 may pass through the gate electrodes 130 below the contact regions 130P, and may pass through the second horizontal conductive layer 104, the horizontal insulating layer 110, and the second substrate 101 to be connected to the circuit interconnection lines 280 in the peripheral circuit structure PERI. The gate contact plugs 175 may be spaced apart from the gate electrodes 130 below the contact regions 130P by contact insulating layers 162. The gate contact plugs 175 may be spaced apart from the second substrate 101, the horizontal insulating layer 110, and the second horizontal conductive layer 104 by the substrate insulating layers 160.

Each of the gate contact plugs 175 may have a shape extending horizontally in the contact region 130P. The contact plug 175 may include a vertical extension portion 175V extending in the Z-direction, and a horizontal extension portion 175H extending horizontally (e.g., in the X-direction) from the vertical extension portion 175V to contact the gate electrode 130. The horizontal extension portion 175H may be disposed along a circumference of the vertical extension portion 175V, and an entire side surface thereof may be surrounded by the gate electrode 130. The gate contact plugs 175 may be spaced apart from the gate electrodes 130 below the contact regions 130P, for example, gate electrodes 130 not electrically connected, by the contact insulating layers 162.

The gate contact plugs 175 may include a conductive material, for example, at least one of tungsten (W), copper (Cu), aluminum (Al), and an alloy thereof. In some implementations, the gate contact plugs 175 may include a barrier layer extending along side and bottom surfaces, or may have an air gap therein.

The contact insulating layers 162 may be arranged to surround a side surface of each of the gate contact plugs 175 below the contact regions 130P. The contact insulating layers 162 may be arranged to be spaced apart from each other in the Z-direction around each of the gate contact plugs 175. The contact insulating layers 162 may be disposed on substantially the same level as the gate electrodes 130. The contact insulating layers 162 may include an insulating material, and may include, for example, silicon oxide, silicon nitride, or silicon oxynitride.

Support structures 165 may be disposed around the gate contact plugs 175. As illustrated in FIG. 3, the support structures 165 may be arranged in the first and second extension regions R2a and R2b and have a circular shape, in a plan view, and may be arranged in a regular shape around the gate contact plugs 175. For example, four support structures 165 may be arranged around one gate contact plug 175, but arrangements are not limited thereto. The support structures 165 may be continuously and regularly arranged in regions in which the contact plugs 175 are spaced apart from each other in the X-direction. The support structures 165 are not limited to circular shapes in a plan view, and may have various shapes such as a polygonal shape, an elliptical shape, or the like. As illustrated in FIG. 4A, a width of each of the support structures 165 may be equal to or smaller than a width of each of the gate contact plugs 175.

The support structures 165 may pass through the gate structures GS to have the same shape as the gate contact plugs 175, as illustrated in FIG. 4A, and may have a cylindrical shape having a width that decreases from each of the support structures 165 in a downward direction. The support structures 165 may be formed of an insulating material.

In the second type bit line through-interconnection regions among the bit line through-interconnection regions TR1 to TR4, for example, the second bit line through-interconnection region TR2, the support structures 165 may function as a vertical structure in the first extension region R2a. The support structures 165 may be formed to pass through the insulation region IR to correspond to the gate contact plugs 175 passing through the gate structures GS, and, in the extension region R2a of the second bit line through-interconnection region TR2, a vertical structure may be disposed and supported only by the support structures 165.

As such, the through-contact plugs 170 of the second type bit line through-interconnection regions may be disposed only in the first region R1, like the first type bit line through-interconnection regions, but the arrangement of the through-contact plugs 170 is not limited thereto. Sub-through-interconnection regions including separate through-contact plugs 170 may be further disposed in the first and second extension regions R2a and R2b.

The interconnection lines 180 may form an upper interconnection structure electrically connected to memory cells in the memory cell structure CELL. The interconnection lines 180 may be electrically connected to, for example, the gate electrodes 130 or the channel structures CH. The number of contact plugs and interconnection lines constituting the interconnection structure may vary in various implementations. The interconnection lines 180 may include metal, and may include, for example, tungsten (W), copper (Cu), aluminum (Al), or the like.

The cell region insulating layer 190 may be disposed to cover the second substrate 101, the gate electrodes 130 on the second substrate 101, and the peripheral region insulating layer 290. The cell region insulating layer 190 may be formed of an insulating material.

In some implementations, the semiconductor device 10 may include a plurality of bypass vias BVa and BVb for electrically connecting the first substrate 201 and the second substrate 101.

As described above, the first bypass vias BVa of the first bypass region BAa and the second bypass vias BVb of the second bypass region BAb in FIGS. 2 and 3 may respectively have the same structure.

Referring to FIGS. 4A and 4B, first and second bypass vias BVa and BVb are illustrated, and the first and second bypass vias BVa and BVb may pass through the peripheral circuit insulating layer 290, and may be in contact with the first substrate 201 at a lower portion of the first and second bypass vias BVa and BVb and the second substrate 101 at an upper portion of the first and second bypass vias BVa and BVb.

An upper width of the first and second bypass vias BVa and BVb may increase as a distance from the first substrate 201 increases.

A channel hole for forming the channel structure CH may be formed by an anisotropic etching process using high energy plasma. In this case, positive charges may accumulate on the second substrate 101 to occur arcing. To prevent this, in some implementations, the positive charges may be discharged by connecting to the first substrate 201 through the bypass vias BVa and BVb.

FIG. 5 illustrates an arrangement of a first substrate 201, a second substrate 101, bypass vias BVa and BVb, and a second bypass region BAb and a first bypass region BAa that may be different from each other. Description provided with respect to FIGS. 1-3 and 4A-4B can equally apply to elements of FIG. 5, except where noted otherwise or suggested otherwise by context.

As described above, the second bypass region Bab and the first bypass region Baa may have different distances d2 and d1 from the first region R1, and the number, densities, and sizes of second bypass vias BVb of the second bypass region Bab may be different. For example, the second bypass vias BVb in the second bypass region Bab may be arranged to discharge positive charges more smoothly than first bypass vias Bva of the first bypass region Baa.

The first bypass vias Bva may be arranged close to a first region R1, and positive charges may be concentrated in a portion of the first bypass vias BVa, in some cases resulting in a defect of melting a lower portion of the first bypass via BVa. In some implementations, to prevent such a defect, a slit SL may be formed in the second substrate 101.

The slit SL may be formed in the second substrate 101 from the first region R1 to a lower portion of a first extension region R2a, including a second type bit line through-interconnection region among a plurality of bit line through-interconnection regions TR1 to TR4. Accordingly, a current path of the positive charges of the second substrate 101 may be distributed and transmitted to the first substrate 201, respectively.

Accordingly, the current may be concentrated and transmitted to some of the first bypass vias BVa to prevent or reduce melting of a lower end of the first bypass via BVa, thereby improving reliability of the semiconductor device 10.

Each of the first and second bypass vias BVa and BVb may have a hole shape on upper surfaces thereof, may be arranged to be spaced apart in the Y-direction, and may be arranged in a plurality of rows, but the arrangement and configuration of the first and second bypass vias BVa and BVb are not limited thereto.

As shown in FIGS. 4A-4B, the first and second bypass vias BVa and BVb may include circuit contact plugs 270 contacting a doped region 215 on the first substrate 201, and circuit interconnection lines 280 disposed between the circuit contact plugs 270, respectively, and may include a connection via 230 disposed between the circuit interconnection lines 280 and the second substrate 101, respectively. The connection via 230 may vertically overlap the circuit contact plugs 270, but the arrangement of the connection via 230 is not limited thereto. For example, the connection via 230 may be arranged not to overlap vertically through the circuit interconnections line 280.

The connection via 230 may be formed to extend from the second substrate 101, and may include a silicon material, and may be, for example, polysilicon or doped polysilicon.

The connection via 230 may include a metal material, and when the connection via 230 is a metal material, the metal material may be a material such as tungsten or the like, e.g., similar to the circuit contact plugs 270.

The first and second bypass vias BVa and BVb may be connected from the second substrate 101 to the doped region 215 of the first substrate 201 through an integrated connection via 230, respectively, but the present disclosure is not limited thereto.

A width of the connection via 230 may decrease in a downward direction, and an upper surface of the second bypass via BVb may be larger than an upper surface of the first bypass via BVa, but the present disclosure is not limited thereto.

The second substrate 101 may be divided into sub-regions on both sides based on the slit SL by including the slit SL cut to an edge region in some regions, and each of the sub-regions may form a current path to the first substrate 201 through each of the first bypass vias BVa to be contacted.

Each of the sub-regions may form a current path to the first substrate 201 through each of the first bypass vias BVa to be contacted, to transmit the current path to the first substrate 201 therebelow, and may be electrically integrated through the circuit contact plugs 270 and the circuit interconnection lines and 280 or the doped region 215.

As an example, a plurality of first bypass vias BVa may be commonly connected to one doped region 215 in the first substrate 201, and may be connected simultaneously by a common circuit interconnection line 280 that may be connected to each of the plurality of first bypass vias BVa, and may be connected to the doped region 215 therebelow. Additionally, a plurality of circuit contact plugs 270 may be disposed between the common circuit interconnections lines 280 and the common doped region 215 to distribute the current path.

In the above, it has been described that the first bypass region BAa and the second bypass region BAb are disposed on left and right sides of the first region R1, but bypass vias are not limited to this arrangement. For example, additional bypass vias may also be disposed in a surplus region of upper and lower portions of the first region R1, but the arrangement is not limited thereto.

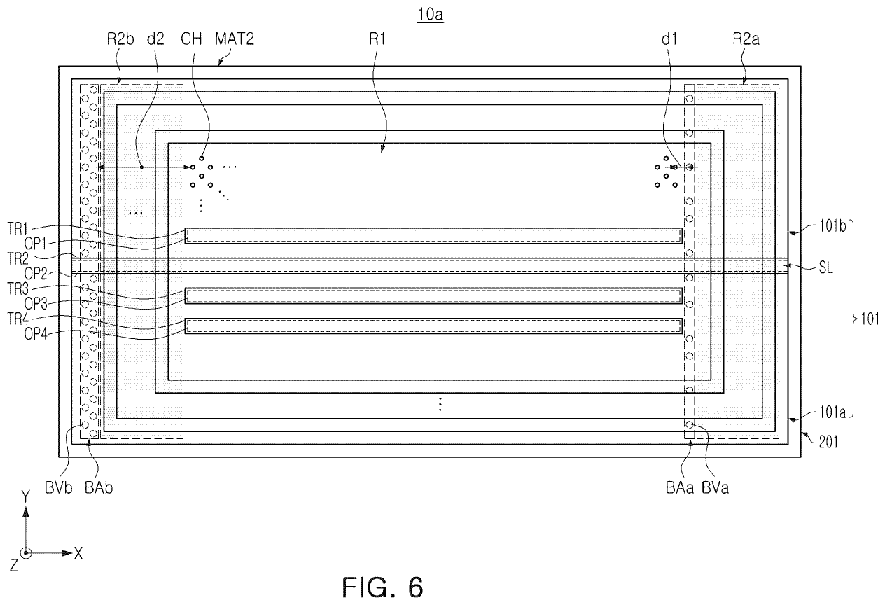

Hereinafter, examples according to the present disclosure will be described with reference to FIGS. 6 to 14. FIGS. 6 to 14 illustrate plan views of a second mat corresponding to FIG. 2 or MAT2 of FIG. 1. The structures shown in FIGS. 6 to 14 can have characteristics as described for the structures of FIGS. 1 to 5, except where noted otherwise or suggested otherwise by context.

Referring to FIG. 6, FIG. 6 may be similar to FIG. 2 in that a second mat MAT2, which may be one of mats MAT1 to MAT4 of a semiconductor device 10a, may include a plurality of bit line through-interconnection regions TR1 to TR4 spaced apart from each other in the Y-direction in a first region R1, a first bypass region BAa between the first region R1 and a first extension region R2a, and a second bypass region BAb outside a second extension region R2b.

At least one of the bit line through-interconnection regions TR1 to TR4 in FIG. 6, for example, a second bit line through-interconnection region TR2, may extend from the first region R1 to both sides in the X-direction, to completely separate a second substrate 101 in a lower portion (in the Z-direction) into two sub-regions 101a and 101b (e.g., discontinuous sub-regions) in the Y-direction. The two sub-regions 101a and 101b, which may be separated from each other, may be electrically connected by contacting a first substrate 201 through bypass vias BVa and BVb respectively contacting the sub-region 101a and 101b.

The two sub-regions 101a and 101b, which may be separated (e.g., spaced apart) from each other, may be electrically connected to the first substrate 201 such that a current path is formed to the first substrate 201 through the bypass vias BVa and BVb in which the sub-regions 101a and 101b are in contact with each other at a first semiconductor structure, and the current path is transmitted to the first substrate 201 therebelow, and the current path is electrically integrated through circuit contact plugs 270 and circuit interconnection lines 280 or a doped region 215. The two sub-regions 101a and 101b may be electrically connected to the first substrate 201 such that the two sub-regions 101a and 101b are connected to a contact plug for applying a common source voltage to the two sub-regions 101a and 101b, and a plurality of contact plugs are electrically integrated in a peripheral circuit structure.

A substrate insulating layer 160 may be disposed in a slit SL, which may be a separation space between the two sub-regions 101a and 101b of the second substrate 101, and the separation space may also extend from one side of the second substrate 101 to the other side thereof, to diversify not only a current path of the first bypass vias BVa of the first bypass region BAa, but also a current path of the second bypass vias BVb of the second bypass region Bab, to distribute load on each of the bypass vias.

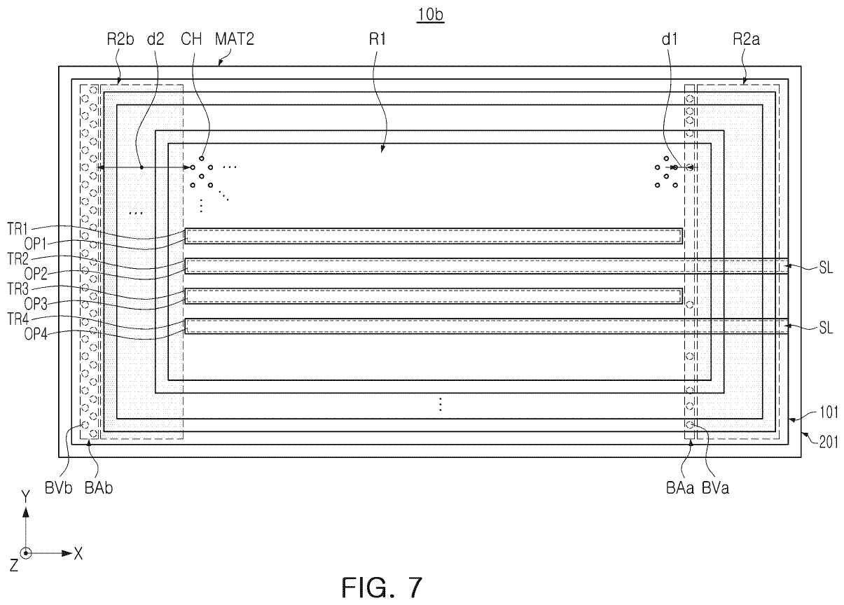

Referring to FIG. 7, FIG. 7 may be similar to FIG. 2 in that a second mat MAT2, which may be one of mats MAT1 to MAT4 of a semiconductor device 10b, may include a plurality of bit line through-interconnection regions TR1 to TR4 spaced apart from each other in the Y-direction in a first region R1, a first bypass region BAa between the first region R1 and a first extension region R2a, and a second bypass region BAb outside a second extension region R2b.

At least two of the bit line through-interconnection regions TR1 to TR4 in FIG. 7, for example, second and fourth bit line through-interconnection regions TR2 and TR4, may be a second type bit line through-interconnection region extending from the first region R1 to the first extension region R2a in the X-direction. A plurality of slits SL may be formed in a second substrate 101 below the second and fourth bit line through-interconnection regions TR2 and TR4. In this case, the first type bit line through-interconnection regions and the second type bit line through-interconnection regions may be spaced apart from each other in the Y-direction, and may be arranged to alternate with each other.

At least one of first bypass vias BVa may be disposed between the plurality of slits SL of the second substrate 101 to transmit a current flowing through the second substrate 101 between the plurality of slits SL to a first substrate 201, to distribute a current path.

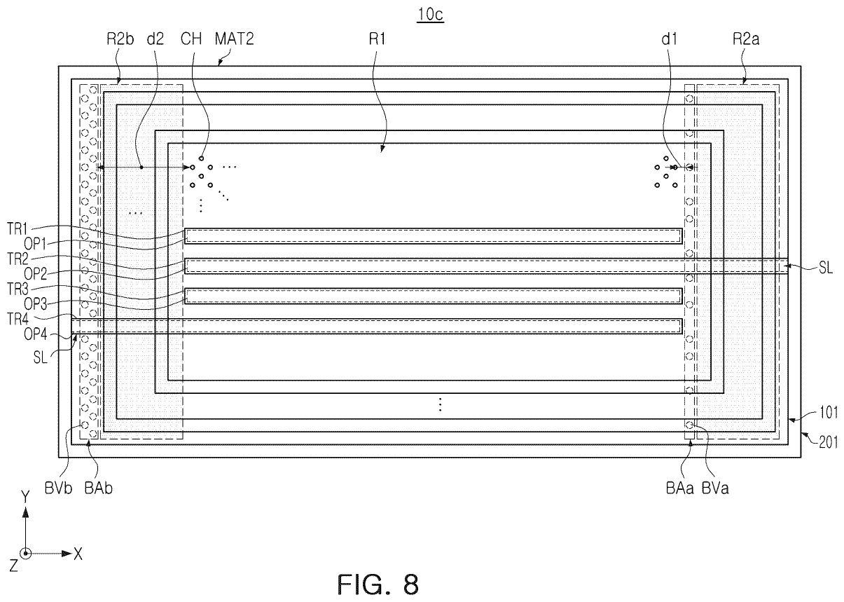

Referring to FIG. 8, in a second mat MAT2, which may be one of mats MAT1 to MAT4 of a semiconductor device 10c, at least two of bit line through-interconnection regions TR1 to TR4, for example, second and fourth bit line through-interconnection regions TR2 and TR4, may extend from a first region R1 to adjacent extension regions R2a or R2b in the X-direction.

For example, the second bit line through-interconnection region TR2 may be a second type bit line through-interconnection region, and may extend from the first region R1 to a first extension region R2a in the X-direction to form a slit SL in a second substrate 101 at a lower portion.

The semiconductor device 10c may further include a third type bit line through-interconnection region TR4 extending from the first region R1 to a second extension region R2b in the X-direction to form a slit SL in the second substrate 101 at the lower portion.

The third type bit line through-interconnection region may form the slit SL in the second substrate 101 at a side, in the X-direction, opposite to that of the second type bit line through-interconnection region.

In the semiconductor device 10c of FIG. 8, the fourth bit line through-interconnection region TR4 may be the third type bit line through-interconnection region, and may extend in a direction, opposite to the second bit line through-interconnection region TR2. For example, the fourth bit line through-interconnection region TR4 may extend from the first region R1 to the second extension region R2b in the X-direction to form a slit SL in the second substrate 101 at the lower portion.

Accordingly, the slits SL of the second substrate 101 may be formed to pass through the first region R1 in different directions, specifically, from different side surfaces of the second substrate 101.

On one side of the second substrate 101, first bypass vias BVa may be disposed on both sides of the slit SL to transmit a current flowing through the second substrate 101 to a first substrate 201, and, on the opposite side thereof, second bypass vias BVb may be disposed on both sides of the slit SL to transmit a current flowing through the second substrate 101 to the first substrate 201, respectively, to diversify a current path to distribute load of the bypass vias BVa and BVb.

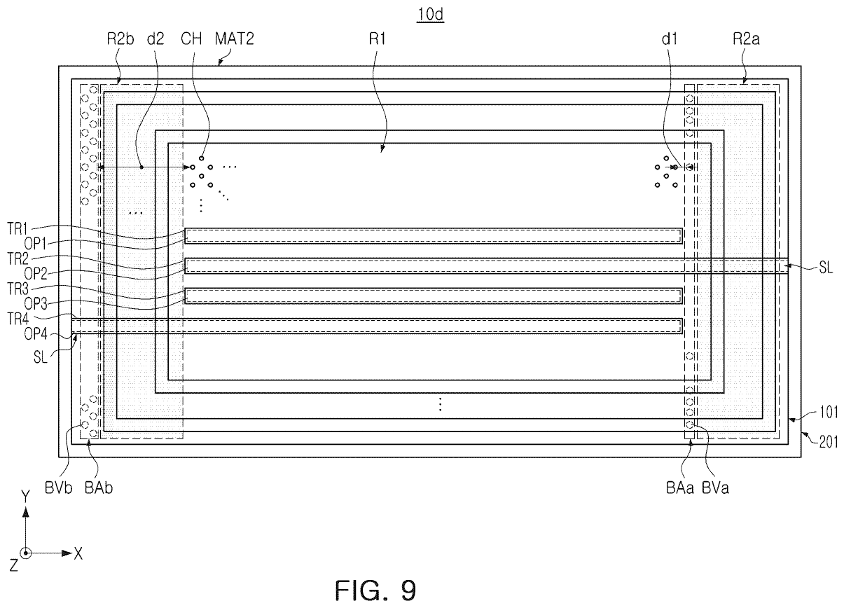

Referring to FIG. 9, a second mat MAT2, which may be one of mats MAT1 to MAT4 of a semiconductor device 10d, may include at least two of bit line through-interconnection regions TR1 to TR4, for example, second and fourth bit line through-interconnection regions TR2 and TR4, that extend from a first region R1 to adjacent extension regions R2a and R2b in the X-direction.

For example, in the semiconductor device 10d, the second bit line through-interconnection region TR2 may be a second type bit line through-interconnection region, similar to the semiconductor device 10c of FIG. 8, and may extend from the first region R1 to a first extension region R2a in the X-direction to form a slit SL in a second substrate 101 at a lower portion. The third type bit line through-interconnection region may form the slit SL in the second substrate 101 in a direction, or at a side, opposite to that of the second type bit line through-interconnection region.

Unlike the semiconductor device 10c of FIG. 8, in the semiconductor device 10d of FIG. 9, bypass vias BVa and BVb in first and second bypass regions BAa and BAb may not be disposed in first to fourth bit line through-interconnection regions TR1 to TR4.

For example, first bypass vias BVa may be disposed, in a limited manner, only in an upper portion of the first bit line through-interconnection region TR1 and a lower portion of the fourth bit line through-interconnection region TR4 even in the first bypass region BAa, and second bypass vias BVb may be disposed, in a limited manner, only in an upper portion of the first bit line through-interconnection region TR1 and a lower portion of the fourth bit line through-interconnection region TR4 even in the second bypass region BAb.

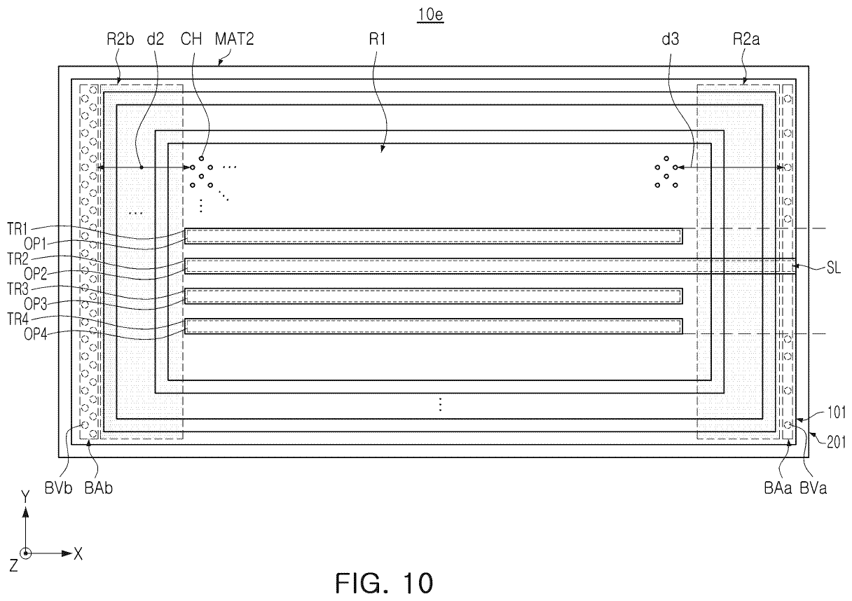

Referring to FIG. 10, FIG. 10 may be similar to FIG. 2 in that a second mat MAT2, which may be one of mats MAT1 to MAT4 of a semiconductor device 10e, may include a plurality of bit line through-interconnection regions TR1 to TR4 spaced apart from each other in the Y-direction in a first region R1, and a second bypass region BAb outside a second extension region R2b.

In the semiconductor device 10e of FIG. 10, a first bypass region BAa may be also disposed outside a first extension region R2a, and may be disposed between an edge region of each of the mats MAT1 to MAT4 and the first extension region R2a.

In this manner, as the first bypass region BAa is disposed outside the first extension region R2a, a distance d3 between the first region R1 and first bypass vias BVa may be expanded to diversify a current path. Therefore, load on the first bypass vias BVa may be reduced while reducing the number of first bypass vias BVa.

In some implementations, at least one of the bit line through-interconnection regions TR1 to TR4, for example, a second bit line through-interconnection region TR2, may extend from the first region R1 to the first extension region R2a to form a slit SL in a second substrate 101.

The first bypass vias BVa may be disposed in the edge region outside the first extension region R2a, and, in some implementations, the first bypass vias BVa may be disposed not to overlap the bit line through-interconnection regions TR1 to TR4 in the X-direction. ‘Not to overlap’ may be defined as not overlapping by being disposed above or below in a substantially vertical direction and not being disposed on the same horizontal line in the X-direction. For example, the first bypass vias BVa may be spaced apart from the bit line through-interconnection regions TR1 to TR4 in the Y-direction.

Based on at least some of the features of FIG. 10, even when the first bypass vias BVa are disposed in a smaller number, a current path may be distributed to each of the first bypass vias BVa by securing a distance from the first region R1.

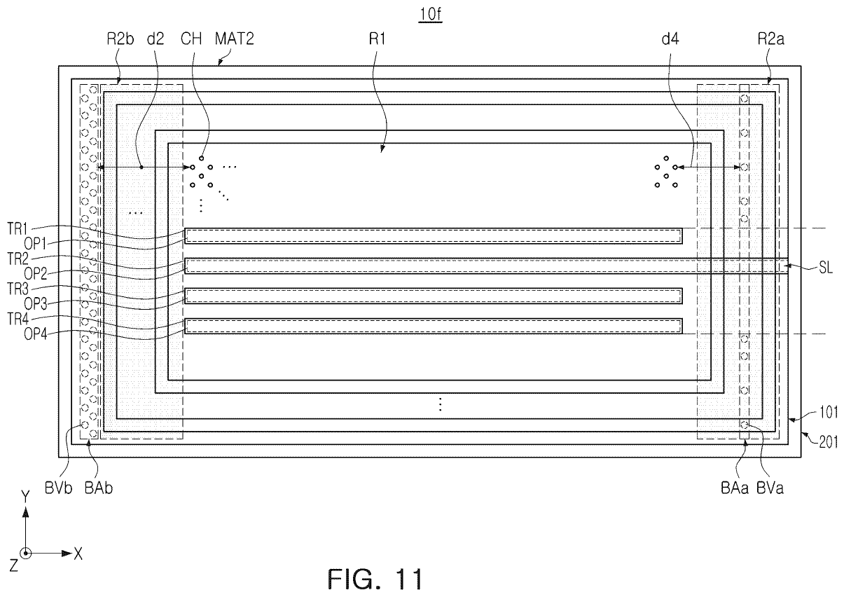

Referring to FIG. 11, FIG. 11 may be similar to FIG. 2 in that a second mat MAT2, which may be one of mats MAT1 to MAT4 of a semiconductor device 10f, may include a plurality of bit line through-interconnection regions TR1 to TR4 spaced apart from each other in the Y-direction in a first region R1, and a second bypass region BAb outside a second extension region R2b.

In the semiconductor device 10f of FIG. 11, a first bypass region BAa may be disposed in a first extension region R2a. A current path may be diversified by increasing a distance d4 between the first region R1 and first bypass vias BVa. Therefore, load on the first bypass vias BVa may be reduced while reducing the number of first bypass vias BVa.

In addition, FIG. 11 may be similar to FIG. 9 in that at least one of the bit line through-interconnection regions TR1 to TR4, for example, a second bit line through-interconnection region TR2, may extend from the first region R1 to the first extension region R2a to form a slit SL in a second substrate 101, and the first bypass vias BVa may be disposed not to overlap the bit line through-interconnection regions TR1 to TR4 in the X-direction (e.g., may be spaced apart from the bit line through-interconnection regions TR1 to TR4 in the Y-direction). Therefore, even when the first bypass vias BVa are disposed in a smaller number, a current path may be distributed to each of the first bypass vias BVa.

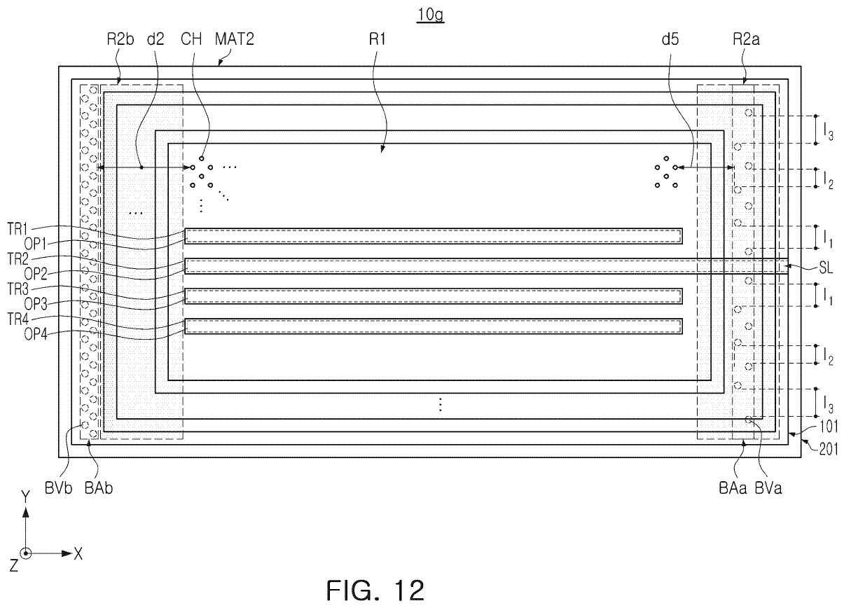

Referring to FIG. 12, FIG. 12 may be similar to FIG. 2 in that a second mat MAT2, which may be one of mats MAT1 to MAT4 of a semiconductor device 10g, may include a plurality of bit line through-interconnection regions TR1 to TR4 spaced apart from each other in the Y-direction in a first region R1, and a second bypass region BAb outside a second extension region R2b, and at least one bit line through-interconnection region (e.g., TR2) may extend to a first extension region R2a.

In the semiconductor device 10g of FIG. 12, a first bypass region BAa may be disposed in the first extension region R2a, and, like the second bypass region BAb, first bypass vias BVa may be arranged in multiple columns. A current path may be diversified by increasing a distance d5 between the first region R1 and the first bypass vias BVa.

In this case, an interval I between the first bypass vias BVa may be set according to the number of channel structures CH in a neighboring first region R1.

For example, the interval I between the first bypass vias BVa disposed close to the first region R1 with a large density of channel structures CH may be set small, and the interval I between the first bypass vias BVa disposed close to the first region R1 with a small density of channel structures CH may be set large. As an example, an upper portion of a first bit line through-interconnection region TR1 and a lower portion of a fourth bit line through-interconnection region TR4, in which the channel structures CH have a high density, may not have the bit line through-interconnection regions TR1 to TR4, and may be a section in which memory blocks are continuous. Therefore, an interval I2 between the first bypass vias BVa disposed close to the first region R1 in which the memory blocks are continuous may be set small, and an interval I1 between the first bypass vias BVa disposed close to the first region R1 with a small density of channel structures CH, like a region in which the bit line through-interconnection regions TR1 to TR4 are disposed, may be set large. Additionally, an interval I3 between the first bypass vias BVa contacting a first substrate including a region in which the channel structures CH are not disposed may be set larger, but the present intervals are not limited thereto.

In this manner, in some implementations, load on the first bypass vias BVa may be reduced by efficiently setting the number and interval (I1, I2, or I3) of the first bypass vias BVa.

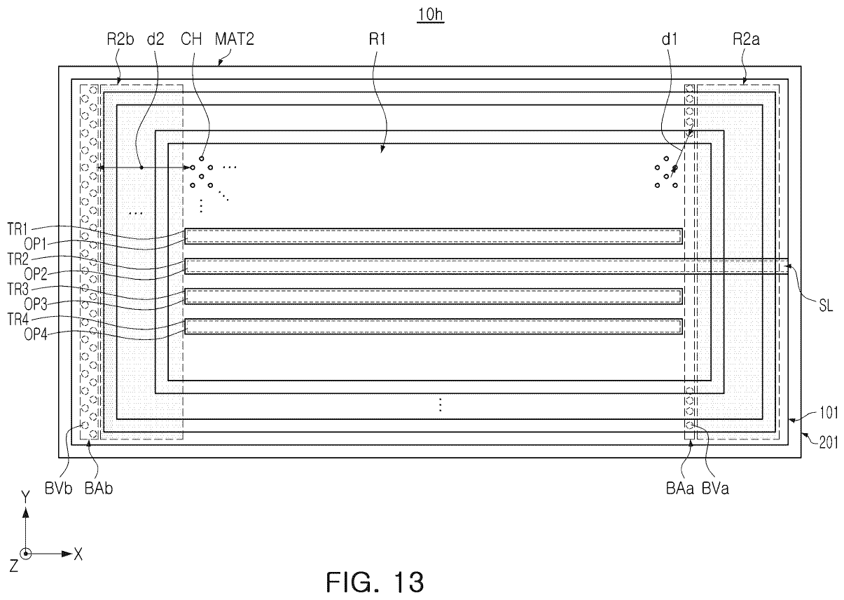

Referring to FIG. 13, FIG. 13 may be similar to FIG. 2 in that a second mat MAT2, which may be one of mats MAT1 to MAT4 of a semiconductor device 10h, may include a plurality of bit line through-interconnection regions TR1 to TR4 spaced apart from each other in the Y-direction in a first region R1, and a second bypass region Bab outside a second extension region R2b, and at least one bit line through-interconnection region (e.g., TR2) may extend to a first extension region R2a.

In the semiconductor device 10h of FIG. 13, a plurality of first bypass vias BVa in a first bypass region BAa may be disposed outside the first region R1.

For example, referring to FIG. 13, the plurality of first bypass vias BVa may not be disposed in the first region R1 in which memory blocks are continuous, but may be disposed, in a limited manner, in an upper (in the Y-direction) surplus region and a lower (in the Y-direction) surplus region in which channel structures CH of the first region R1 are not disposed. Therefore, a distance d1 between the first region R1 and the first bypass vias BVa may increase to diversify a current path.

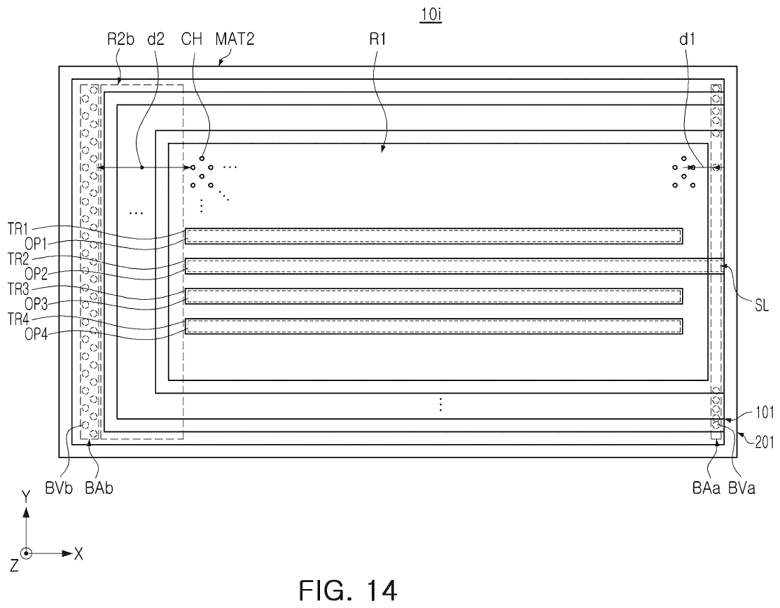

Referring to FIG. 14, in a second mat MAT2, which may be one of mats MAT1 to MAT4 of a semiconductor device 10i, an extension region R2b may be disposed on one side of a first region R1 and an extension region may not be disposed on the other side of the first region R1. For example, an extension region may not be disposed on both edges of the first region R1 that faces a neighboring mat MAT1, and the extension region R2b may be disposed only on an edge of a chip.

As such, when the extension region R2b is disposed only on one side of the first region R1, an edge region may be disposed on the other side of the first region R1, and a first bypass region BAa may be disposed in a lower portion of the edge region.

As in FIG. 2, at least one bit line through-interconnection region (e.g., TR2) may extend to the edge region, and first bypass vias BVa may be connected to channel structures CH of an adjacent first region R1, and the first bypass vias BVa and the channel structures CH may be spaced apart from each other by a first separation distance d1 or more. The first bypass vias BVa may not be disposed in a region parallel to a first bit line through-interconnection region TR1 to a fourth bit line through-interconnection region TR4, and the first bypass vias BVa may be mainly disposed in other regions, e.g., may be spaced apart from the bit line through-interconnection regions TR1 to TR4 in the Y-direction.

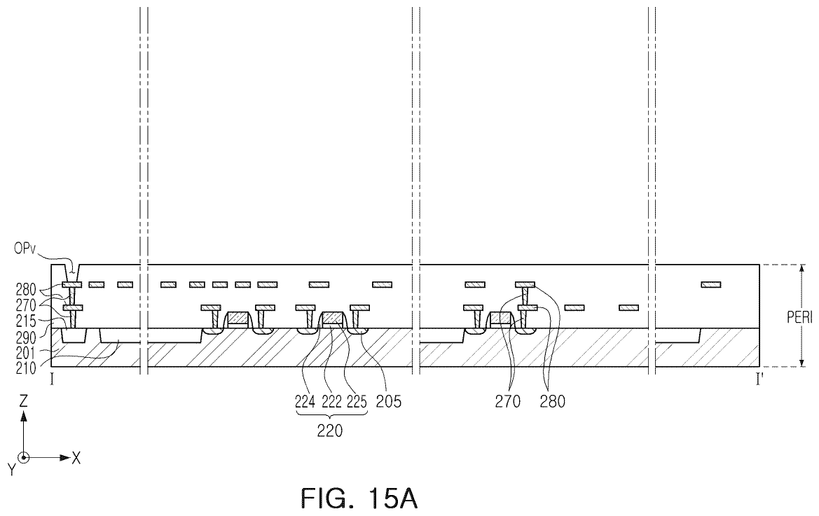

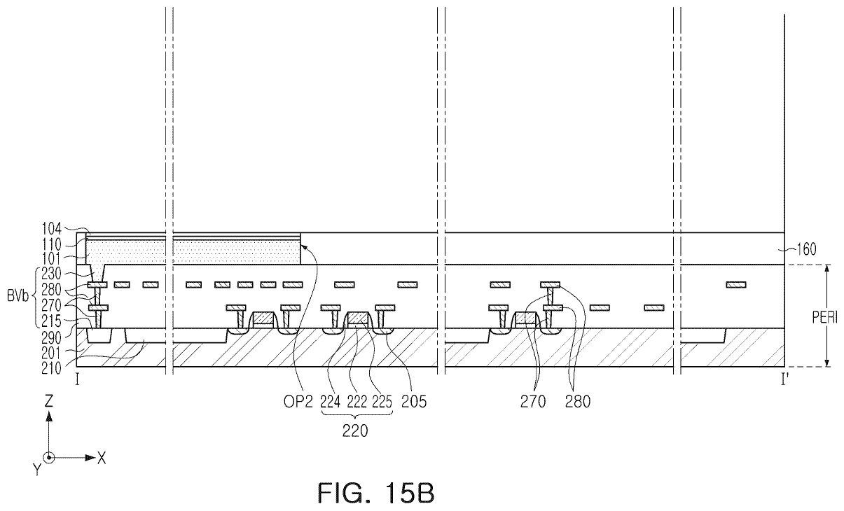

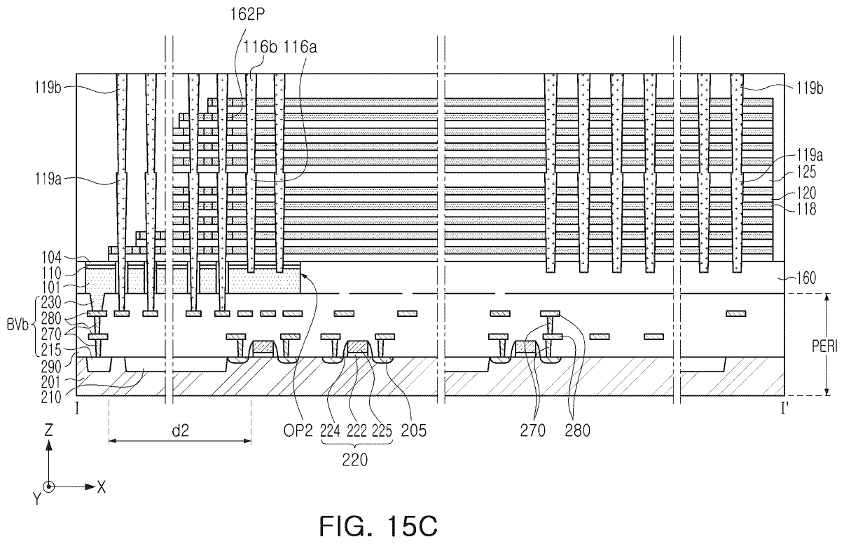

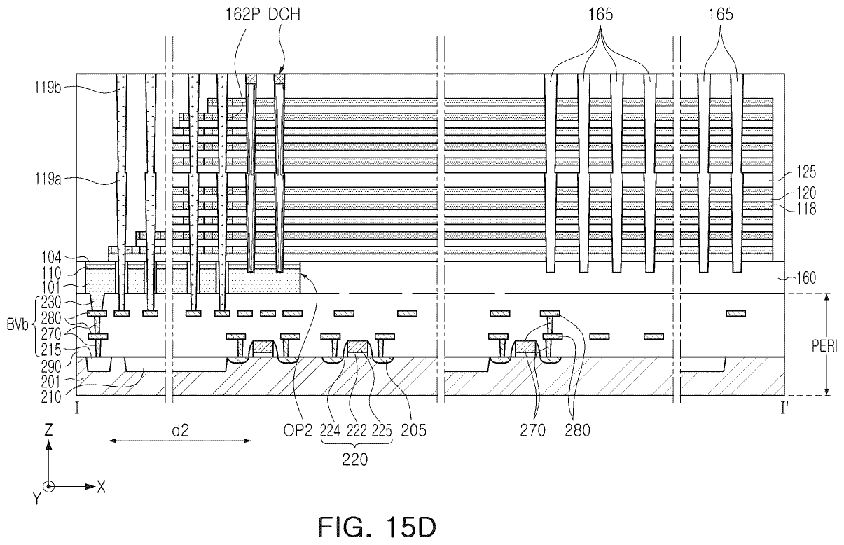

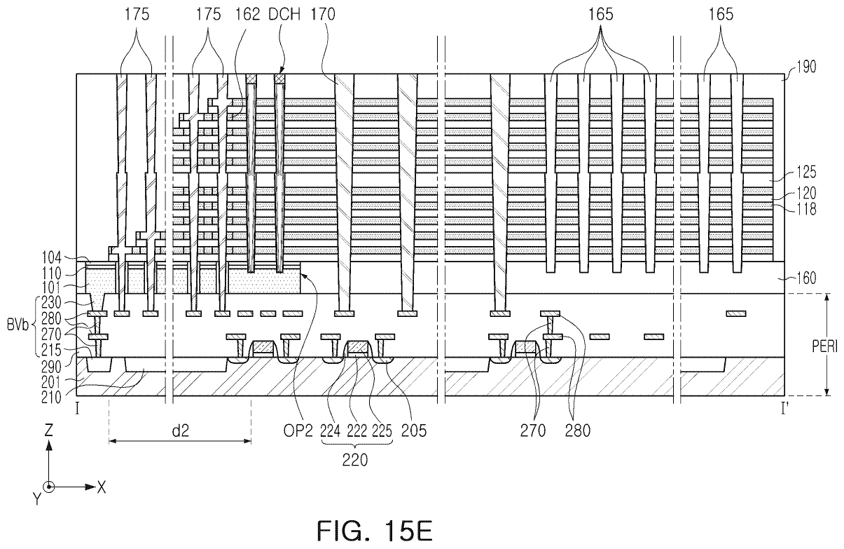

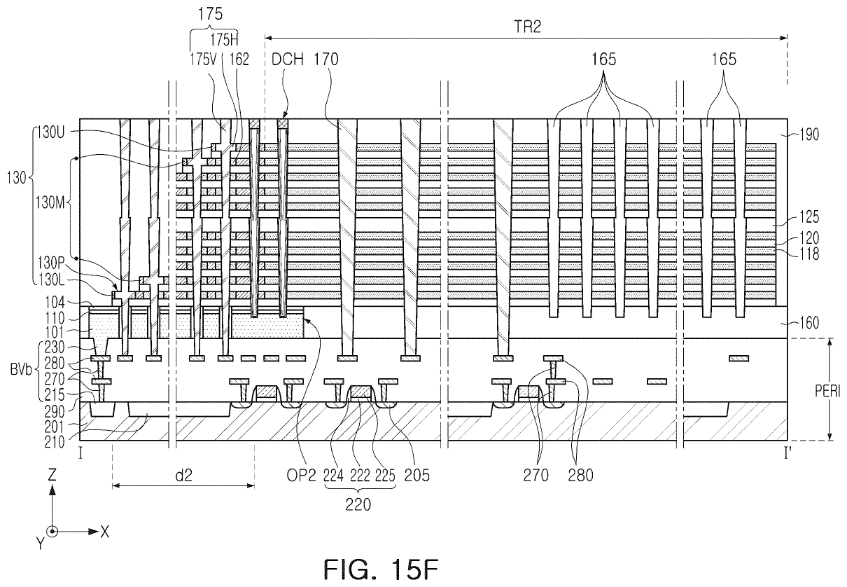

FIGS. 15A to 15F are schematic cross-sectional views illustrating a method of manufacturing a semiconductor device according to some implementations. FIGS. 15A to 15F illustrate a region corresponding to FIG. 4A.

Referring to FIG. 15A, circuit elements 220 and a portion of lower interconnection structures may be formed on a first substrate 201.

First, element isolation layers 210 may be formed in the first substrate 201, and a circuit gate dielectric layer 222 and a circuit gate electrode 225 may be sequentially formed on the first substrate 201. The element isolation layers 210 may be formed by, for example, a shallow trench isolation (STI) process. The circuit gate dielectric layer 222 and the circuit gate electrode 225 may be formed using atomic layer deposition (ALD) or chemical vapor deposition (CVD). The circuit gate dielectric layer 222 may be formed of silicon oxide, and the circuit gate electrode 225 may be formed of at least one of polycrystalline silicon or a metal silicide layer, but the materials are not limited thereto. Next, a spacer layer 224, source/drain regions 205, and doped regions 215 (bypass contact regions) may be formed on both sidewalls of the circuit gate dielectric layer 222 and the circuit gate electrode 225. In some implementations, the spacer layer 224 may be formed as a plurality of layers. Next, an ion implantation process may be performed to form the source/drain regions 205 and the doped regions 215.

Among the circuit interconnection structures, circuit contact plugs 270 may be prepared by forming a portion of a peripheral region insulating layer 290, removing portion by etching, and burying the peripheral region insulating layer 290 with a conductive material. Circuit interconnection lines 280 may be formed, for example, by depositing and then patterning a conductive material.

The peripheral region insulating layer 290 may be formed as a plurality of insulating layers. The peripheral region insulating layer 290 may be partially formed in each operation of forming the circuit interconnection structures, and may be partially formed above an uppermost circuit interconnection line 280, to be finally formed to cover the circuit elements 220 and the circuit interconnection structures.

To form bypass vias BVa and BVb, via holes OPv may be formed to open the circuit interconnection lines 280 of the circuit interconnection structures connected to the doped regions 215.

As illustrated in FIG. 5, the via holes OPv, separated from each other, may be formed to align with the bypass vias BVa and BVb of a first bypass region BAa and a second bypass region BAb.

Next, referring to FIG. 15B, a second substrate 101, a horizontal insulating layer 110, a second horizontal conductive layer 104, and a substrate insulating layer 160, in which a memory cell region CELL is provided, may be formed on a peripheral circuit region PERI.

For example, the second substrate 101 may be formed while filling a plurality of via holes OPv and forming the bypass vias BVa and BVb, and an upper surface of the second substrate 101 may be formed to be flat. For this purpose, the second substrate 101 may be formed of polysilicon, and may be formed by a CVD process. The polysilicon may include an impurity, but the present disclosure is not limited thereto.

First and second horizontal insulating layers forming the horizontal insulating layer 110 may be alternately stacked on the second substrate 101. The horizontal insulating layer 110 may be a layer that may be partially replaced with a first horizontal conductive layer 102, as in FIG. 4B, by a subsequent process. First horizontal insulating layers may include a different material than a second horizontal insulating layer. For example, the first horizontal insulating layers may be formed of the same material as interlayer insulating layers 120, and the second horizontal insulating layers may be formed of the same material as subsequent sacrificial insulating layers 118. The horizontal insulating layer 110 may be removed from some regions, for example, a second region R2 of the second substrate 101, by a patterning process.

The second horizontal conductive layer 104 may be formed on the horizontal insulating layer 110, and may be in contact with the second substrate 101 in a region in which the horizontal insulating layer 110 has been removed. Therefore, the second horizontal conductive layer 104 may be bent along end portions of the horizontal insulating layer 110, may cover the end portions, and may extend onto the second substrate 101.

After forming the second substrate 101, the first horizontal insulating layer 110, and the second horizontal conductive layer 104 as a whole, a process of removing the second substrate 101, the first horizontal insulating layer 110, and the second horizontal conductive layer 104 may be performed to respectively open lower portions of bit line through-interconnection regions TR1 to TR4. A slit SL may be formed in the second substrate 101 corresponding to at least one bit line through-interconnection region (TR1 to TR4) of the bit line through-interconnection regions TR1 to TR4, and, in some implementations, the second substrate 101 may be divided into a plurality of sub-regions. Additionally, the second substrate 101, the first horizontal insulating layer 110, and the second horizontal conductive layer 104 may be partially removed to open a lower portion of a region in which gate contact plugs 175 are disposed. When a plurality of mats MAT1 to MAT4 are formed for one semiconductor chip and one peripheral circuit region PERI, the second substrate 101 may be removed between each of the mats MAT1 to MAT4. In this manner, the substrate insulating layer 160 may be formed by filling an insulating material in a region from which the second substrate 101, the first horizontal insulating layer 110, and the second horizontal conductive layer 104 are removed. After filling the insulating material, a planarization process may be further performed using a chemical mechanical polishing (CMP) process. As a result, an upper surface of the substrate insulating layer 160 may be substantially coplanar with an upper surface of the second horizontal conductive layer 104. As a result, formation of the slit SL of the second substrate 101, formation of a separation or division structure of the second substrate 101, and formation of each of the bypass vias BVa and BVb may be completed, and accordingly, a current path may be diversified in the bypass vias BVa and BVb.

Next, referring to FIG. 15C, first, the sacrificial insulating layers 118 and the interlayer insulating layers 120 may be alternately stacked on the second horizontal conductive layer 104 to form a preliminary stack structure. In this operation, the sacrificial insulating layers 118 and the interlayer insulating layers 120 may be formed in a height region in which first channel structures CH1 (see FIG. 4A) are disposed. A relatively thick upper interlayer insulating layer 125 may be formed at the top.

The sacrificial insulating layers 118 may be a layer that may be replaced with gate electrodes 130 (see FIG. 4A) by a subsequent process. The sacrificial insulating layers 118 may be formed of a material different from the interlayer insulating layers 120, and may be formed of a material that may be etched with etch selectivity with respect to the interlayer insulating layers 120 under specific etching conditions. For example, the interlayer insulating layer 120 and the upper interlayer insulating layer 125 may be formed of at least one of silicon oxide or silicon nitride, and the sacrificial insulating layers 118 may be formed of a material selected from silicon, silicon oxide, silicon carbide, and silicon nitride, different from the interlayer insulating layer 120. In some implementations, the interlayer insulating layers 120 may not all have the same thickness. Moreover, thicknesses of the interlayer insulating layers 120 and the sacrificial insulating layers 118 and the number of constituting films thereof may be changed from those illustrated.

Next, a photolithography process and an etching process may be repeatedly performed on the sacrificial insulating layers 118 using a mask layer such that upper sacrificial insulating layers 118 extend shorter than lower sacrificial insulating layers 118 in the first region R1. As a result, the sacrificial insulating layers 118 may form a stepped structure in a predetermined unit, and contact regions 130P located in an uppermost portion of the sacrificial insulating layers 118 may be exposed in an upward direction.

First sacrificial channel layers 116a may be formed in a region of the first region R1 corresponding to the first channel structures CH1 (see FIG. 4A). The first sacrificial channel layers 116a may be prepared by forming lower channel holes to pass through the lower stack structure, and then depositing a material forming the first sacrificial channel layers 116a in the lower channel holes. The first sacrificial channel layers 116a may include, for example, polycrystalline silicon.

Second sacrificial channel layers 116b may be prepared by forming upper channel holes on the first sacrificial channel layers 116a such that upper ends of the first sacrificial channel layers 116a are exposed through the upper stack structure. After that, the second sacrificial channel layers 116b may be formed by depositing a material on the upper channel holes. The second sacrificial channel layers 116b may include, for example, polycrystalline silicon.

In this case, first vertical sacrificial layers 119a and second vertical sacrificial layers 119b may be formed in succession in regions corresponding to gate contact plugs 175 and support structures 165. Formation of the first and second vertical sacrificial layers 119a and 119b may proceed in the same manner as formation of the first and second sacrificial channel layers 116a and 116b, but a preliminary contact insulating layer 162P may be formed on side surfaces of the vertical sacrificial layers 119a and the second vertical sacrificial layers 119b of the gate contact plugs 175.

Referring to FIG. 15D, the first and second sacrificial channel layers 116a and 116b may be removed to form channel structures CH, and the first and second vertical sacrificial layers 119a and 119b may be removed to form support structures 165.

The channel structures CH may be formed by removing the first and second sacrificial channel layers 116a and 116b to form channel holes and then filling the channel holes. For example, a cell region insulating layer 190 may be formed to cover the stack structure, and a gate dielectric layer 145, a channel layer 140, a channel buried insulating layer 150, and a channel pad may be sequentially formed in the channel holes passing through the cell region insulating layer 190 and the stack structure, to form the channel structures CH. The channel layer 140 may be formed of a conductive material, and may be formed of, for example, polycrystalline silicon.

In some implementations, the stack structure may form a lower stack structure, may form a lower stepped structure and a portion of the cell region insulating layer 190 covering the same, may form an upper stack structure on the lower stack structure, and may then additionally form an upper stepped structure and a remaining cell region insulating layer 190. In this case, to form the channel structures CH, a lower channel hole passing through the lower stepped structure, and an upper channel hole passing through the upper stepped structure may be formed separately. Therefore, the channel structures CH may include a lower channel structure CH1 corresponding to the lower channel hole, and an upper channel structure CH2 corresponding to the upper channel hole.

Additionally, the support structures 165 may be formed by removing the vertical sacrificial layers 119a and 119b in a region corresponding to the support structures 165 and filling them with an insulating material.

As illustrated in FIG. 15E, gate contact plugs 175 may be formed, and through-contact plugs 170 (see FIG. 3) may be formed in the bit line through-interconnection regions TR1 to TR4.

Openings may be formed by removing the first vertical sacrificial layer 119a and the second vertical sacrificial layer 119b in a region in which the gate contact plugs 175 of FIG. 3 are formed. Before forming the openings, a portion of the cell region insulating layer 190 covering the channel structures CH may be further formed. The openings may have a cylindrical hole shape, may pass through the substrate insulating layer 160, and may extend to the peripheral circuit structure PERI.

After removing the preliminary contact insulating layer 162P of the contact region 130P through the openings, a portion of the preliminary contact insulating layer 162P in a lateral direction may be removed to form contact insulating layers 162, and a conductive material may be deposited in the openings to form gate contact plugs 175.

The contact insulating layers 162 may include, for example, an insulating material such as an oxide, silicon oxide, or the like. The gate contact plugs 175 may be formed to have horizontal extension portions 175H (see FIG. 4A) in the contact regions 130P, thereby physically and electrically connecting to the gate electrodes 130.

Via holes VH passing through the cell region insulating layer 190 and an insulating region IR may be formed. The circuit interconnection line 280 of the peripheral circuit structure PERI may be exposed from lower ends of the via holes VH.

The bit line through-interconnection regions TR1 to TR4 may be formed by filling the via holes VH with a conductive material to form through-contact plugs 170.

Referring to FIG. 15F, the sacrificial insulating layers 118 may be replaced with gate electrodes 130, except for a region in which the bit line through-interconnection regions TR1 to TR4 are formed.

First, openings may be formed in a region in which separation regions MS1 and MS2 are formed, and the sacrificial insulating layers 118 may be removed by flowing an etchant through the openings. The gate electrodes 130 may be formed in a tunnel opening region from which the sacrificial insulating layers 118 have been removed. In this case, since each of the bit line through-interconnection regions TR1 to TR4 may be spaced apart from the openings of the separation regions MS1 and MS2, the etchant may not reach. Therefore, the sacrificial insulating layers 118 may remain to maintain the insulating regions IR. Therefore, a region in which the sacrificial insulating layers 118 remain in the bit line through-interconnection regions TR1 to TR4 may not coincide with a region in which the substrate insulating layer 160 is disposed. Therefore, when the bit line through-interconnection regions TR1 to TR4 are defined based on the substrate insulating layer 160, the sacrificial insulating layers 118 may be described as being located not only in the bit line through-interconnection regions TR1 to TR4, but also around the bit line through-interconnection regions TR1 to TR4.

The semiconductor device 10 may be manufactured by forming the gate electrodes 130, filling the openings with the separation insulating layer 105, and then forming interconnection lines 180 connected to upper ends of the channel structures CH, the gate contact plugs 175, and the through-contact plugs 170.

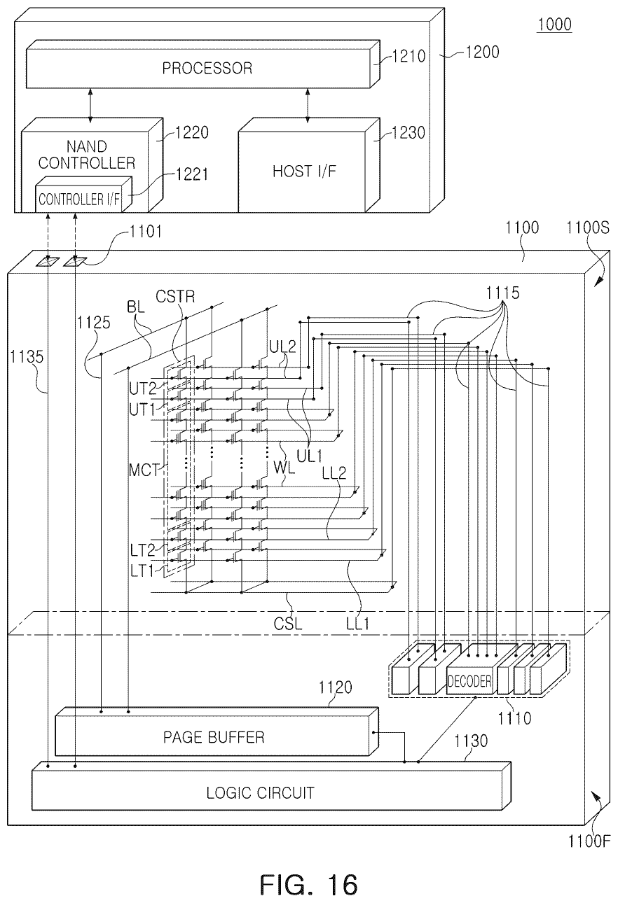

FIG. 16 is a view schematically illustrating a data storage system including a semiconductor device according to some implementations.

Referring to FIG. 16, a data storage system 1000 may include a semiconductor device 1100, and a controller 1200 electrically connected to the semiconductor device 1100. The data storage system 1000 may be a storage device including the semiconductor device 1100 as a single semiconductor device or a plurality of semiconductor devices, or an electronic device including the storage device. For example, the data storage system 1000 may be a solid state drive device (SSD), a universal serial bus (USB), a computing system, a medical device, or a communication device, including the semiconductor device 1100 as a single semiconductor device or a plurality of semiconductor devices.

The semiconductor device 1100 may be a non-volatile memory device, for example, a NAND flash memory device described above with reference to FIGS. 1 to 14. The semiconductor device 1100 may include a first structure 1100F, and a second structure 1100S on the first structure 1100F. In some implementations, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including bit lines BL, a common source line CSL, word lines WL, first and second upper gate lines UL1 and UL2, first and second lower gate lines LL1 and LL2, and memory cell strings CSTR between each of the bit lines BL and the common source line CSL.

In the second structure 1100S, each of the memory cell strings CSTR may include lower transistors LT1 and LT2 adjacent to the common source line CSL, upper transistors UT1 and UT2 adjacent to each of the bit lines BL, and a plurality of memory cell transistors MCT disposed between each of the lower transistors LT1 and LT2 and each of the upper transistors UT1 and UT2. The number of lower transistors LT1 and LT2 and the number of upper transistors UT1 and UT2 may vary in various implementations.

In some implementations, each of the upper transistors UT1 and UT2 may include a string select transistor, and each of the lower transistors LT1 and LT2 may include a ground select transistor. The lower gate lines LL1 and LL2 may be gate electrodes of the lower transistors LT1 and LT2, respectively. The word lines WL may be gate electrodes of the memory cell transistors MCT, and the upper gate lines UL1 and UL2 may be gate electrodes of the upper transistors UT1 and UT2, respectively.

In some implementations, the lower transistors LT1 and LT2 may include a lower erase control transistor LT1 and a ground select transistor LT2, connected in series. The upper transistors UT1 and UT2 may include a string select transistor UT1 and an upper erase control transistor UT2, connected in series. At least one of the lower erase control transistor LT1 or the upper erase control transistor UT2 may be used for an erase operation of erasing data stored in the memory cell transistors MCT using a gate-induced-drain-leakage (GIDL) phenomenon.

The common source line CSL, the first and second lower gate lines LL1 and LL2, the word lines WL, and the first and second upper gate lines UL1 and UL2 may be electrically connected to the decoder circuit 1110 through first connection interconnections 1115 extending from the first structure 1100F into the second structure 1100S. The bit lines BL may be electrically connected to the page buffer 1120 through second connection interconnections 1125 extending from the first structure 1100F into the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through input/output connection interconnections 1135 extending from the first structure 1100F into the second structure 1100S.

The controller 1200 may include a processor 1210, a NAND controller 1220, and a host interface 1230. In some implementations, the data storage system 1000 may include a plurality of semiconductor devices 1100, and in this case, the controller 1200 may control the plurality of semiconductor devices 1100.

The processor 1210 may control an overall operation of the data storage system 1000 including the controller 1200. The processor 1210 may operate according to a predetermined firmware, and may access the semiconductor device 1100 by controlling the NAND controller 1220. The NAND controller 1220 may include a controller interface 1221 processing communications with the semiconductor device 1100. A control command for controlling the semiconductor device 1100, data to be written to the memory cell transistors MCT of the semiconductor device 1100, data to be read from the memory cell transistors MCT of the semiconductor device 1100, or the like may be transmitted through the controller interface 1221. The host interface 1230 may provide a communication function between the data storage system 1000 and an external host. When a control command is received from the external host through the host interface 1230, the processor 1210 may control the semiconductor device 1100 in response to the control command.

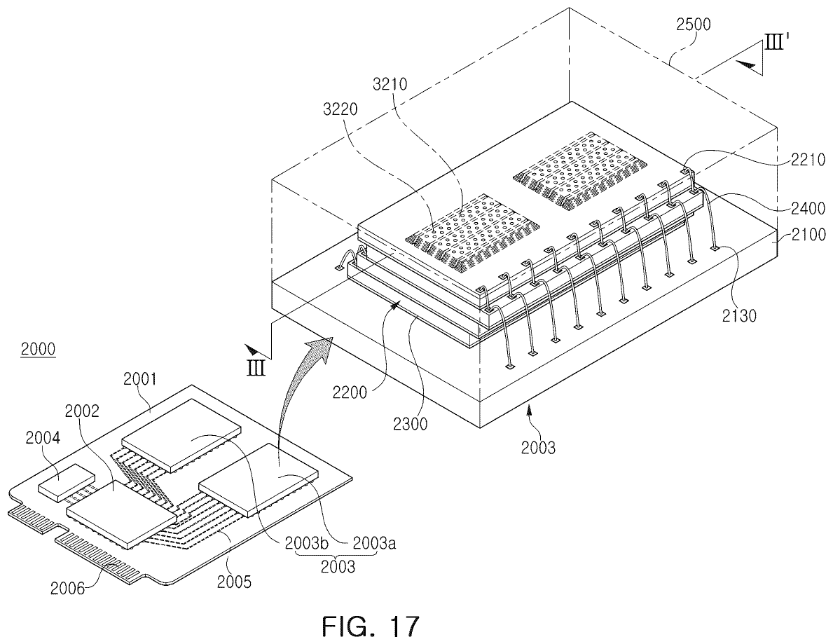

FIG. 17 is a perspective view schematically illustrating an data storage system including a semiconductor device according to some implementations.

Referring to FIG. 17, a data storage system 2000 according to some implementations may include a main substrate 2001, a controller 2002 mounted on the main substrate 2001, at least one semiconductor package 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins, which may be coupled to an external host. The number and arrangement of the plurality of pins in the connector 2006 may be changed according to a communication interface between the data storage system 2000 and the external host. In some implementations, the data storage system 2000 may be communicated with the external host according to any one interface of a universal serial bus (USB), peripheral component interconnect express (PCI-Express), serial advanced technology attachment (SATA), M-Phy for universal flash storage (UFS), or the like. In some implementations, the data storage system 2000 may be operated by power supplied from the external host through the connector 2006. The data storage system 2000 may further include a power management integrated circuit (PMIC) distributing power, supplied from the external host, to the controller 2002 and the semiconductor package 2003.

The controller 2002 may write data to the semiconductor package 2003 or read data from the semiconductor package 2003, and may improve an operation speed of the data storage system 2000.

The DRAM 2004 may be a buffer memory reducing a difference in speed between the semiconductor package 2003, which may be a data storage space, and the external host. The DRAM 2004 included in the data storage system 2000 may also operate as a type of cache memory, and may provide a space temporarily storing data in a control operation on the semiconductor package 2003. When the DRAM 2004 is included in the data storage system 2000, the controller 2002 may further include a DRAM controller controlling the DRAM 2004 in addition to a NAND controller controlling the semiconductor package 2003.

The semiconductor package 2003 may include first and second semiconductor packages 2003a and 2003b, spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting each of the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input/output pad 2210. The input/output pad 2210 may correspond to the input/output pad 1101 of FIG. 16. Each of the semiconductor chips 2200 may include a gate stack structure 3210 and a memory channel structure 3220. Each of the semiconductor chips 2200 may include the semiconductor device described above with reference to FIGS. 1 to 14.

In some implementations, the connection structure 2400 may be a bonding wire electrically connecting the input/output pad 2210 and the package upper pads 2130. Therefore, in each of the first and second semiconductor packages 2003a and 2003b, the semiconductor chips 2200 may be electrically connected to each other by a bonding wire process, and may be electrically connected to the package upper pads 2130 of the package substrate 2100. In some implementations, in each of the first and second semiconductor packages 2003a and 2003b, the semiconductor chips 2200 may be electrically connected to each other by a connection structure including through-contact plugs 170 (e.g., a through silicon via (TSV)), instead of a connection structure 2400 by a bonding wire process.

In some implementations, the controller 2002 and the semiconductor chips 2200 may be included in one (1) package. In some implementations, the controller 2002 and the semiconductor chips 2200 may be mounted on a separate interposer substrate, different from the main substrate 2001, and the controller 2002 and the semiconductor chips 2200 may be connected to each other by a wiring formed on the interposer substrate.

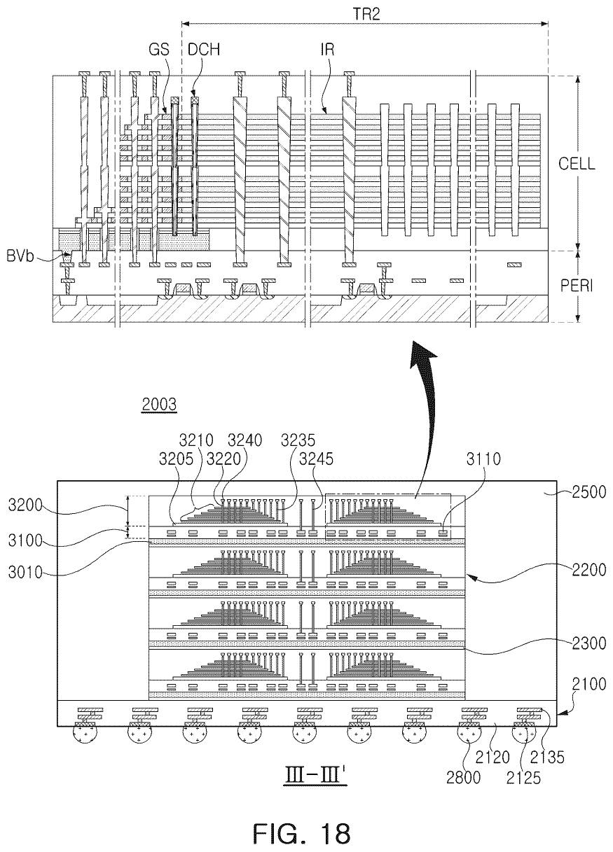

FIG. 18 is a cross-sectional view schematically illustrating a semiconductor package according to some implementations. FIG. 18 illustrates an example of the semiconductor package 2003 of FIG. 17, and conceptually illustrates a region taken along line III-III′ of the semiconductor package 2003 of FIG. 17.

Referring to FIG. 18, in the semiconductor package 2003, the package substrate 2100 may be a printed circuit board. The package substrate 2100 may include a package substrate body portion 2120, package upper pads 2130 (refer to FIG. 14) disposed on an upper surface of the package substrate body portion 2120, package lower pads 2125 disposed on a lower surface of the package substrate body portion 2120 or exposed from the lower surface, and internal interconnections 2135 electrically connecting the package upper pads 2130 and the package lower pads 2125 in the package substrate body portion 2120. The package upper pads 2130 may be electrically connected to the connection structures 2400. The package lower pads 2125 may be connected to the wiring patterns 2005 of the main substrate 2001 of the data storage system 2000, as illustrated in FIG. 14, through conductive connection portions 2800.

Each of the semiconductor chips 2200 may include a semiconductor substrate 3010, and a first structure 3100 and a second structure 3200, sequentially stacked on the semiconductor substrate 3010. The first structure 3100 may include a peripheral circuit region including peripheral interconnections 3110. The second structure 3200 may include a common source line 3205, a gate stack structure 3210 on the common source line 3205, memory channel structures 3220 and separation regions, passing through the gate stack structure 3210, bit lines 3240 electrically connected to the memory channel structures 3220, and gate contact plugs 3235 electrically connected to word lines WL (see FIG. 17) of the gate stack structure 3210. As described above with reference to FIGS. 1 to 14, each of the semiconductor chips 2200 may include bypass vias for bypass connection between a substrate of the first structure 3100 and a substrate of the second structure 3200, and at least one slit may be formed in the substrate of the second structure 3200 to distribute load of the bypass vias.

Each of the semiconductor chips 2200 may include a through-interconnection 3245 electrically connected to the peripheral interconnections 3110 of the first structure 3100 and extending into the second structure 3200. The through-interconnection 3245 may be disposed outside the gate stack structure 3210, and may further be disposed to pass through the gate stack structure 3210. Each of the semiconductor chips 2200 may further include an input/output pad 2210 (see FIG. 17) electrically connected to the peripheral interconnections 3110 of the first structure 3100.

Positive charges may be removed by dividing a substrate on which channel structures are disposed into a plurality of sub-regions, and connecting each of the sub-regions and the substrate therebelow with respective bypass vias. Therefore, a defect in which a lower portion of each of the bypass vias melts may be reduced or prevented by distributing load overloaded to a portion of the bypass vias.

Load may be distributed by forming a slit in a region in which bypass vias are overloaded on a substrate on which a channel structure is disposed, to diversify a current path. Therefore, a problem of deteriorating reliability of a semiconductor device due to a defect in a specific bypass via may be mitigated by distributing load in a limited space allocated to the bypass vias.

Therefore, semiconductor devices having improved reliability, and data storage systems including the same, may be provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While examples have been illustrated and described above, it will be apparent to those skilled in the art that modifications and variations could be made without departing from the scope of the present inventive concept as defined by the appended claims.

What is claimed is:

1. A semiconductor device comprising:
a first semiconductor structure including a first substrate, circuit elements on the first substrate, and circuit interconnection lines on the circuit elements;
a second semiconductor structure including a second substrate disposed on the first semiconductor structure, the second semiconductor structure having a first region, a first extension region disposed on a side of the first region, and a second extension region disposed on an opposite side of the first region; and
bypass vias electrically connecting the first substrate and the second substrate,
wherein the second semiconductor structure includes:
gate electrodes stacked on the second substrate and spaced apart from each other in a first direction that is perpendicular to a surface of the second substrate;
channel structures extending in the first direction through the gate electrodes in the first region;
separation regions extending through the gate electrodes in the first direction and extending in a second direction that is perpendicular to the first direction, wherein the separation regions are spaced apart from each other in a third direction that is perpendicular to the first and second directions;
gate contact plugs contacting the gate electrodes, wherein the gate electrodes extend in the first and second extension regions with a step shape; and
through-interconnection regions including through-contact plugs extending through the second substrate and extending in the first direction to electrically connect the first semiconductor structure and the second semiconductor structure to one another in the first region, the through-interconnection regions including an insulating region surrounding the through-contact plugs,
wherein at least one through-interconnection region, of the through-interconnection regions, passes through the second substrate and extends in the second direction from the first region to the first extension region.

2. The semiconductor device of claim 1, wherein the bypass vias comprise first bypass vias spaced apart from each other in a first bypass region disposed on the side of the first region, and second bypass vias spaced apart from each other in a second bypass region disposed on the opposite side of the first region.

3. The semiconductor device of claim 2, wherein a number of the first bypass vias is less than a number of the second bypass vias.

4. The semiconductor device of claim 2, wherein the second substrate is divided into a plurality of sub-regions by the at least one through-interconnection region extending from the first region to the first extension region, and
wherein each of the plurality of sub-regions is electrically connected to the first substrate through the first bypass vias.

5. The semiconductor device of claim 2, wherein the first bypass vias are spaced apart from the through-interconnection regions not to overlap the through-interconnection regions in the third direction.

6. The semiconductor device of claim 2, wherein the first bypass region comprises the first bypass vias spaced apart from each other in the third direction between the first region and the first extension region.

7. The semiconductor device of claim 2, wherein the first bypass region comprises the first bypass vias arranged in a plurality of rows in the first extension region, wherein distances between adjacent ones of at least some of the first bypass vias vary.

8. The semiconductor device of claim 1, wherein the through-interconnection regions are disposed in a central portion of the first region, and wherein the second substrate comprises at least one slit extending in the second direction at a lower portion of the at least one through-interconnection region, the at least one slit extending from the first region to the first extension region.

9. The semiconductor device of claim 1, wherein the through-interconnection regions comprise:
first through-interconnection regions extending in the first region in the second direction and spaced apart in the third direction; and
at least one second through-interconnection region spaced apart from the first through-interconnection regions in the third direction and between adjacent ones of the first through-interconnection regions, wherein the at least one second through-interconnection region comprises the at least one through-interconnection region extending from the first region to the first extension region.

10. The semiconductor device of claim 9, wherein the at least one second through-interconnection region extends from the first region to the second extension region to separate the second substrate into a plurality of sub-regions.

11. The semiconductor device of claim 10, wherein the plurality of sub-regions separated from each other are electrically connected through the first semiconductor structure.

12. The semiconductor device of claim 9, wherein the through-interconnection regions further comprise at least one third through-interconnection region spaced apart from the first through-interconnection regions in the third direction and extending in the second direction from the first region to the second extension region.

13. A semiconductor device comprising:
a first semiconductor structure including a first substrate, circuit elements on the first substrate, circuit interconnection lines on the circuit elements, and a first substrate insulating layer covering the circuit interconnection lines;
a second semiconductor structure including a second substrate disposed on the first semiconductor structure, the second semiconductor structure having a first region, a first extension region disposed on a side of the first region, and a second extension region disposed on an opposite side of the first region; and
bypass vias extending through the first substrate insulating layer and electrically connecting the first substrate and the second substrate,
wherein the second substrate includes at least one slit extending from the first region to the first extension region.

14. The semiconductor device of claim 13, wherein the bypass vias comprise first bypass vias spaced apart from each other in a first bypass region disposed on the side of the first region, and second bypass vias spaced apart from each other in a second bypass region disposed on the opposite side of the first region.

15. The semiconductor device of claim 14, wherein a number of the first bypass vias is less than a number of the second bypass vias.

16. The semiconductor device of claim 14, wherein the second substrate is divided into a plurality of sub-regions by the at least one slit extending from the first region to the first extension region, and
wherein each of the plurality of sub-regions is electrically connected to the first substrate through the first bypass vias.

17. The semiconductor device of claim 14, wherein a distance from the first region to the first bypass region is smaller than a distance from the first region to the second bypass region.

18. The semiconductor device of claim 13, wherein the at least one slit of the second substrate passes through the second extension region, the first region, and the first extension region, to separate the second substrate into a plurality of sub-regions.

19. A data storage system comprising:
a semiconductor storage device including a first semiconductor structure including a first substrate, circuit elements on the first substrate, and circuit interconnection lines on the circuit elements;
a second semiconductor structure including a second substrate disposed on the first semiconductor structure, the second semiconductor structure having a first region, a first extension region disposed on a side of the first region, and a second extension region disposed on an opposite side of the first region;
bypass vias electrically connecting the first substrate and the second substrate;
an input/output pad electrically connected to the circuit elements; and
a controller electrically connected to the semiconductor storage device through the input/output pad and configured to control the semiconductor storage device,
wherein the second semiconductor structure includes:
gate electrodes stacked on the second substrate and spaced apart from each other in a first direction that is perpendicular to a surface of the second substrate;
channel structures extending in the first direction through the gate electrodes in the first region;
separation regions extending through the gate electrodes in the first direction and extending in a second direction that is perpendicular to the first direction, wherein the separation regions are spaced apart from each other in a third direction that is perpendicular to the first and second directions;
gate contact plugs contacting the gate electrodes, wherein the gate electrodes extend in the first and second extension regions with a step shape; and
through-interconnection regions including through-contact plugs extending through the second substrate and extending in the first direction to electrically connect the first semiconductor structure and the second semiconductor structure to one another in the first region, the through-interconnection regions including an insulating region surrounding the through-contact plugs,
wherein at least one through-interconnection region, of the through-interconnection regions, passes through the second substrate and extends in the second direction from the first region to the first extension region.

20. The data storage system of claim 19, wherein the bypass vias comprise first bypass vias spaced apart from each other in a first bypass region disposed on the side of the first region, and second bypass vias spaced apart from each other in a second bypass region disposed on the opposite side of the first region,
wherein a number of the first bypass vias is less than a number of the second bypass vias.
